(19) United States
(12) Patent Application Publication
(10) Pub. No.: US 2013/0038402 A1
(43) Pub. Date: Feb. 14, 2013

(54) WIRELESS POWER COMPONENT SELECTION

(71) Applicants: Aristeidis Karalis, Boston, MA (US); Morris P. Kesler, Bedford, MA (US); Katherine L. Hall, Arlington, MA (US); Andrew J. Campanella, Somerville, MA (US); Andre B. Kurs, Chestnut Hill, MA (US)

(72) Inventors: Aristeidis Karalis, Boston, MA (US); Morris P. Kesler, Bedford, MA (US); Katherine L. Hall, Arlington, MA (US); Andrew J. Campanella, Somerville, MA (US); Andre B. Kurs, Chestnut Hill, MA (US)

(73) Assignee: WITRICITY CORPORATION, Watertown, MA (US)

(21) Appl. No.: 13/589,992

(22) Filed: Aug. 20, 2012

Related U.S. Application Data
(63) Continuation-in-part of application No. 13/555,807, filed on Jul. 23, 2012.
(60) Provisional application No. 61/525,087, filed on Aug. 18, 2011.
(60) Provisional application No. 61/510,459, filed on Jul. 21, 2011.

(51) Int. Cl. H03H 7/38

(52) U.S. Cl. 333/32

(57) ABSTRACT

A method includes providing a source resonator including a first conductive loop in parallel with a first capacitive element and in series with a first adjustable element the source resonator having a source target impedance, providing a plurality of device resonators each including a conductive loop and having a device target impedance, connecting, for each of the plurality of device resonators, a resistor corresponding to the device target impedance in series with the conductive loop of each of the plurality of device resonators, connecting a network analyzer in series with the first conductive loop and adjusting at least one of the first capacitive element and the first adjustable element until a measured impedance of the source resonator is within a predetermined range of the source target impedance.

### CROSS-REFERENCE TO RELATED APPLICATIONS

This application claims the benefit of U.S. Provisional patent application 61/525,087 filed Aug. 18, 2011. This application is also a continuation-in-part of U.S. Ser. No. 13/555,807, filed Jul. 23, 2012, which claims the benefit of U.S. Provisional patent application 61/510,459 filed Jul. 21, 2011. All of which are incorporated herein by reference.

### BACKGROUND

1. Field

This disclosure relates to wireless energy transfer, methods, systems and apparati to accomplish such transfer, and applications.

2. Description of the Related Art

Energy or power may be transferred wirelessly using a variety of known radiative, or far-field, and non-radiative, or near-field, techniques as detailed, for example, in commonly owned U.S. patent application Ser. No. 12/613,686 published on May 6, 2010 as US 2010/010909445 and entitled “Wireless Energy Transfer Systems,” U.S. patent application Ser. No. 12/860,375 published on Dec. 9, 2010 as 2010/0308939 and entitled “Integrated Resonator-Shield Structures,” U.S. patent application Ser. No. 13/222,915 published on Mar. 15, 2012 as 2012/0062345 and entitled “Low Resistance Electrical Conductor,” U.S. patent application 13/283,811 published on ______ as ______ and entitled “Multi-Resonator Wireless Energy Transfer for Lighting,” the contents of which are incorporated by reference. Prior art wireless energy transfer systems have been limited by a variety of factors including concerns over user safety, low energy transfer efficiencies and restrictive physical proximity/alignment tolerances for the energy supply and sink components.

One particular challenge in wireless energy transfer is control and tuning of the resonator structures and the power source. Other resonators, temperature, extraneous objects, and the like may affect the parameters of the resonators. The impedance, resonant frequency, loading conditions, and/or parameters of electrical components, and the like, may fluctuate during operation of the wireless energy transfer system. In embodiments components used to make of manufacture wireless energy components may have a range of tolerances or component value variability and may require fine tuning of components during assembly or manufacture to tune the resonators and wireless energy transfer components within an acceptable range.

Therefore a need exists for methods and designs for tuning components of a wireless energy transfer system.

### SUMMARY

Various systems and processes, in various embodiments, provide wireless energy transfer using coupled resonators. In some embodiments, the resonator structures may require or benefit from tuning of the components of the resonators. Resonators, electrical components, and parameters of an energy source may require tuning to maintain a specific level of efficiency or performance. The features of such embodiments are general and may be applied to a wide range of resonators, regardless of the specific examples discussed herein.

In embodiments, a magnetic resonator may comprise some combination of inductors and capacitors. Additional circuit elements such as capacitors, inductors, resistors, switches, and the like, may be inserted between a magnetic resonator and a power source, and/or between a magnetic resonator and a power load. In this disclosure, the conducting coil that comprises the high-Q inductive loop of the resonator may be referred to as the inductor and/or the inductive load. The inductive load may also refer to the inductor when it is wirelessly coupled (through a mutual inductance) to other system or extraneous objects. In this disclosure, circuit elements other than the inductive load may be referred to as being part of an impedance matching network or IMN. It is to be understood that all, some, or none of the elements that are referred to as being part of an impedance matching network may be part of the magnetic resonator. Which elements are part of the resonator and which are separate from the resonator will depend on the specific magnetic resonator and wireless energy transfer system design.

In one aspect, a fixed tuned wireless energy power modules comprising at least one magnetic resonator may be fined tuned using a temporary matching resistor. The module may be tuned by first determining a target impedance for the resonator and then connecting a temporary matching resistor in series with the resonator inductive loop. Additional electrical components such as capacitors, inductors, resistors, amplifiers, rectifiers, and the like are connected to the matching resistor and the resonator inductive loop. The values of the electrical components are adjusted until the actual impedance of the resonator loop and the components are within an acceptable range of the target impedance. In embodiments the acceptable range may be within 20% or within 10% of the target impedance. In embodiments the temporary matching resistor may be connected to the resonator loop using fuses, jumpers, switches, and the like or may be soldered or attached by other means. After the target impedance is reached the temporary resistor may be removed and the connection shorted. The resonator inductive loop and the additional electrical components may be attached to a power source or a amplifier. In embodiments the resonator inductive loop and the additional electrical components may be attached to a power load such as a rectifier.

In another aspect a resonator may be tuned to a target impedance using a temporary resistor. A temporary resistor is connected in series with a resonator loop, the resistor chosen to simulate the loading of at least one additional resonator and adjusting circuit elements in the resonator until the actual impedance of the resonator is within 10% or 20% of a target impedance.

Unless otherwise indicated, this disclosure uses the terms wireless energy transfer, wireless power transfer, wireless power transmission, and the like, interchangeably. Those skilled in the art will understand that a variety of system architectures may be supported by the wide range of wireless system designs and functionalities described in this application.

In the wireless energy transfer systems described herein, power may be exchanged wirelessly between at least two resonators. Resonators may supply, receive, hold, transfer, and distribute energy. Sources of wireless power may be referred to as sources or supplies and receivers of wireless power may be referred to as devices, receivers and power loads. A resonator may be a source, a device, or both, simultaneously or may vary from one function to another in a controlled manner. Resonators configured to hold or distribute energy that do not have wired connections to a power supply or power drain may be called repeaters.

The resonators of the wireless energy transfer systems of this invention are able to transfer power over distances that are large compared to the size of the resonators themselves. That is, if the resonator size is characterized by the radius of the smallest sphere that could enclose the resonator structure, the wireless energy transfer system of this invention can transfer power over distances greater than the characteristic size of a resonator. The system is able to exchange energy between resonators where the resonators have different characteristic sizes and where the inductive elements of the resonators have different sizes, different shapes, are comprised of different materials, and the like.

The wireless energy transfer systems of this invention may be described as having a coupling region, an energized area or volume, all by way of describing that energy may be transferred between resonant objects that are separated from each other, they may have variable distance from each other, and that may be moving relative to each other. In some embodiments, the area or volume over which energy can be transferred is referred to as the active field area or volume. In addition, the wireless energy transfer system may comprise more than two resonators that may each be coupled to a power source, a power load, both, or neither.

Wirelessly supplied energy may be used to power electric or electronic equipment, recharge batteries or charge energy storage units. Multiple devices may be charged or powered simultaneously or power delivery to multiple devices may be serialized such that one or more devices receive power for a period of time after which power delivery may be switched to other devices. In various embodiments, multiple devices may share power from one or more sources with one or more other devices either simultaneously, or in a time multiplexed manner, or in a frequency multiplexed manner, or in a spatially multiplexed manner, or in an orientation multiplexed manner, or in any combination of time and frequency and spatial and orientation multiplexing. Multiple devices may share power with each other, with at least one device being reconfigured continuously, intermittently, periodically, occasionally, or temporarily, to operate as a wireless power source. Those of ordinary skill in the art will understand that there are a variety of ways to power and/or charge devices applicable to the technologies and applications described herein.

This disclosure references certain individual circuit components and elements such as capacitors, inductors, resistors, diodes, transformers, switches and the like; combinations of these elements as networks, topologies, circuits, and the like; and objects that have inherent characteristics such as “self-resonant” objects with capacitance or inductance distributed (or partially distributed, as opposed to solely lumped) throughout the entire object. It would be understood by one of ordinary skill in the art that adjusting and controlling variable components within a circuit or network may adjust the performance of that circuit or network and that those adjustments may be described generally as tuning, adjusting, matching, correcting, and the like. Other methods to tune or adjust the operating point of the wireless power transfer system may be used alone, or in addition to adjusting tunable components such as inductors and capacitors, or banks of inductors and capacitors. Those skilled in the art will recognize that a particular topology discussed in this disclosure can be implemented in a variety of other ways.

Unless otherwise defined, all technical and scientific terms used herein have the same meaning as commonly understood by one of ordinary skill in the art to which this disclosure belongs. In case of conflict with publications, patent applications patents, and other references mentioned or incorporated herein by reference, the present specification, including definitions, will control.

Any of the features described above may be used, alone or in combination without departing from the scope of this disclosure. Other features, objects, and advantages of the systems and methods disclosed herein will be apparent from the following detailed description and figures.

In accordance with an exemplary and non-limiting embodiment, a method comprises providing a source resonator comprising a first conductive loop in parallel with a first capacitive element and in series with a first adjustable element the source resonator having a source target impedance, providing a device resonator comprising a second conductive loop in parallel with a second capacitive element and in series with a second adjustable element the device resonator having a device target impedance, providing a repeater resonator, arranging a position of the repeater resonator substantially between a position of the source resonator and a position of the device resonator, connecting a resistor corresponding to the device target impedance in series with the second conductive loop, connecting a network analyzer in series with the first conductive loop, adjusting at least one of the first capacitive element and the first adjustable element until a measured impedance of the source resonator is within a predetermined range of the source target impedance, connecting a resistor corresponding to the source target impedance in series with the first conductive loop, connecting the network analyzer in series with the second conductive loop and adjusting at least one of the second capacitive element and the second adjustable element until a measured impedance of the device resonator is within a predetermined range of the device target impedance.

In accordance with an exemplary and non-limiting embodiment, a method comprises providing a source resonator comprising a first conductive loop in parallel with a first capacitive element and in series with a first adjustable element the source resonator having a source target impedance, providing a plurality of device resonators each comprising a conductive loop and having a device target impedance, connecting, for each of the plurality of device resonators, a resistor corresponding to the device target impedance in series with the conductive loop of each of the plurality of device resonators, connecting a network analyzer in series with the first conductive loop and adjusting at least one of the first capacitive element and the first adjustable element until a measured impedance of the source resonator is within a predetermined range of the source target impedance.

### BRIEF DESCRIPTION OF FIGURES

FIG. 1 is a system block diagram of wireless energy transfer configurations according to an exemplary and non-limiting embodiment;

FIGS. 2A-2E are exemplary structures and schematics of simple resonator structures according to exemplar and non-limiting embodiments;

FIG. 3 is a block diagram of a wireless source with a single-ended amplifier according to an exemplary and non-limiting embodiment;

FIG. 4 is a block diagram of a wireless source with a differential amplifier according to an exemplary and non-limiting embodiment;

FIGS. 5A and 5B are block diagrams of sensing circuits according to exemplary and non-limiting embodiments;

FIGS. 6A, 6B, and 6C are block diagrams of a wireless source according to exemplary and non-limiting embodiments;

FIG. 7 is a plot showing the effects of a duty cycle on the parameters of an amplifier according to an exemplary and non-limiting embodiment;

FIG. 8 is a simplified circuit diagram of a wireless power source with a switching amplifier according to an exemplary and non-limiting embodiment;

FIG. 9 shows plots of the effects of changes of parameters of a wireless power source according to an exemplary and non-limiting embodiment;

FIG. 10 shows plots of the effects of changes of parameters of a wireless power source according to an exemplary and non-limiting embodiment;

FIGS. 11A, 11B, and 11C are plots showing the effects of changes of parameters of a wireless power source according to an exemplary and non-limiting embodiment;

FIG. 12 shows plots of the effects of changes of parameters of a wireless power source according to an exemplary and non-limiting embodiment;

FIG. 13 is a simplified circuit diagram of a wireless energy transfer system comprising a wireless power source with a switching amplifier and a wireless power device according to an exemplary and non-limiting embodiment;

FIG. 14 shows plots of the effects of changes of parameters of a wireless power source according to an exemplary and non-limiting embodiment;

FIG. 15A shows a configuration for taking measurements of a resonator loop, FIG. 15b shows a configuration for taking measurements of an assembly of a resonator loop with a capacitor according to an exemplary and non-limiting embodiment;

FIG. 16A and FIG. 16B show configurations for taking measurements of a resonator loop using an external measurement coil according to an exemplary and non-limiting embodiment;

FIG. 17 shows a configuration for taking measurements of a resonator loop using an external measurement coil when loaded by other resonator coils according to an exemplary and non-limiting embodiment;

FIG. 18 shows a configuration for taking measurements of a resonator loop during tuning operations according to an exemplary and non-limiting embodiment;

FIG. 19 shows a configuration for taking measurements of a type 1 resonator assembly according to an exemplary and non-limiting embodiment;

FIG. 20 shows a configuration for taking measurements of a type 2 resonator assembly according to an exemplary and non-limiting embodiment;

FIG. 21 shows a Type 1 arrangement and a Type 2 arrangement according to an exemplary and non-limiting embodiment;

FIG. 22 shows a measurement configuration for tuning adjustment for systems with a repeater according to an exemplary and non-limiting embodiment;

FIG. 23 shows a measurement configuration for tuning adjustment for systems with a repeater according to an exemplary and non-limiting embodiment;

FIG. 24 shows a measurement configuration for tuning adjustment for systems with multiple devices according to an exemplary and non-limiting embodiment;

FIG. 25 is a flow diagram of a method according to an exemplary and non-limiting embodiment; and

FIG. 26 is a flow diagram of a method according to an exemplary and non-limiting embodiment.

### DETAILED DESCRIPTION

As described above, this disclosure relates to wireless energy transfer using coupled electromagnetic resonators. However, such energy transfer is not restricted to electromagnetic resonators, and the wireless energy transfer systems described herein are more general and may be implemented using a wide variety of resonators and resonant objects.

As those skilled in the art will recognize, important considerations for resonator-based power transfer include resonator efficiency and resonator coupling. Extensive discussion of such issues, e.g., coupled mode theory (CMT), coupling coefficients and factors, quality factors (also referred to as Q-factors), and impedance matching is provided, for example, in U.S. patent application Ser. No. 12/789,611 published on Sep. 23, 2010 as US 20100237709 and entitled “RESONATOR ARRAYS FOR WIRELESS ENERGY TRANSFER,” and U.S. patent application Ser. No. 12/722,050 published on Jul. 22, 2010 as US 20100181843 and entitled “WIRELESS ENERGY TRANSFER FOR REFRIGERATOR APPLICATION” and incorporated herein by reference in its entirety as if fully set forth herein.

A resonator may be defined as a resonant structure that can store energy in at least two different forms, and where the stored energy oscillates between the two forms. The resonant structure will have a specific oscillation mode with a resonant (modal) frequency, f, and a resonant (modal) field. The angular resonant frequency, ω, may be defined as ω=2πf, the resonant period, T, may be defined as T=1/f=2π/ω, and the resonant wavelength, λ, may be defined as λ=c/f, where c is the speed of the associated field waves (light, for electromagnetic resonators). In the absence of loss mechanisms, coupling mechanisms or external energy supplying or draining mechanisms, the total amount of energy stored by the resonator, W, would stay fixed, but the form of the energy would oscillate between the two forms supported by the resonator, wherein one form would be maximum when the other is minimum and vice versa.

For example, a resonator may be constructed such that the two forms of stored energy are magnetic energy and electric energy. Further, the resonator may be constructed such that the electric energy stored by the magnetic field is primarily confined within the structure while the magnetic energy stored by the magnetic field is primarily in the region surrounding the resonator. In other words, the total electric and magnetic energies would be equal, but their localization would be different. Using such structures, energy exchange between at least two structures may be mediated by the resonant magnetic near-field of the at least two resonators. These types of resonators may be referred to as magnetic resonators.

An important parameter of resonators used in wireless power transmission systems is the Quality Factor, or Q-factor, or Q, of the resonator, which characterizes the energy decay and is inversely proportional to energy losses of the resonator. It may be defined as Q=ω*W/P, where P is the time-averaged power loss at steady state. That is, a resonator with a high-Q has relatively low intrinsic losses and can store energy for a relatively long time. Since the resonator loses energy at its intrinsic decay rate, 2Γ, its Q, also referred to as its intrinsic Q, is given by Q=ω/2Γ. The quality factor also represents the number of oscillation periods, T, it takes for the energy in the resonator to decay by a factor of e. Note that the quality factor or intrinsic quality factor or Q of the resonator is that due only to intrinsic loss mechanisms. The Q of a resonator connected to, or coupled to a power generator, g, or load, l, may be called the “loaded quality factor” or the “loaded Q”. The Q of a resonator in the presence of an extraneous object that is not intended, to be part of the energy transfer system may be called the “perturbed quality factor” or the “perturbed Q”.

Resonators having substantially the same resonant frequency, coupled through any portion of their near-fields may interact and exchange energy. By way of example, but not limitation, imagine a source resonator with Qₛ and a device resonator with Q_{d}. High-Q wireless energy transfer systems may utilize resonators that are high-Q. The Q of each resonator may be high. The geometric mean of the resonator Q's, \sqrt{QₛQ_{d}} may also or instead be high.

The coupling factor, k, is a number between 0≦k≦1, and it may be independent (or nearly independent) of the resonant frequencies of the source and device resonators, when those are placed at sub-wavelength distances. Rather the coupling factor k may be determined mostly by the relative geometry and the distance between the source and device resonators where the physical decay-law of the field mediating their coupling is taken into account. The coupling coefficient used in CMT, κ=k\sqrt{ωₛω_{d}}/2, may be a strong function of the resonant frequencies, as well as other properties of the resonator structures. In applications for wireless energy transfer utilizing the near-fields of the resonators, it is desirable to have the size of the resonator be much smaller than the resonant wavelength, so that power lost by radiation is minimized. In some embodiments, high-Q resonators are sub-wavelength structures. In some electromagnetic embodiments, high-Q resonator structures are designed to have resonant frequencies higher than 100 kHz. In other embodiments, the resonant frequencies may be less than 1 GHz.

In exemplary embodiments, the power radiated into the far-field by these sub wavelength resonators may be further reduced by lowering the resonant frequency of the resonators and the operating frequency of the system. In other embodiments, the far field radiation may be reduced by arranging for the far fields of two or more resonators to interfere destructively in the far field.

In a wireless energy transfer system a resonator may be used as a wireless energy source, a wireless energy capture device, a repeater or a combination thereof. In embodiments a resonator may alternate between transferring energy, receiving energy or relaying energy. In a wireless energy transfer system one or more magnetic resonators may be coupled to an energy source and be energized to produce an oscillating magnetic near-field. Other resonators that are within the oscillating magnetic near-fields may capture these fields and convert the energy into electrical energy that may be used to power or charge a load thereby enabling wireless transfer of useful energy.

The so-called “useful” energy in a useful energy exchange is the energy or power that must be delivered to a device in order to power or charge it at an acceptable rate. The transfer efficiency that corresponds to a useful energy exchange may be system or application-dependent. For example, high power vehicle charging applications that transfer kilowatts of power may need to be at least 80% efficient in order to supply useful amounts of power resulting in a useful energy exchange sufficient to recharge a vehicle battery without significantly heating up various components of the transfer system. In some consumer electronics applications, a useful energy exchange may include any energy transfer efficiencies greater thin 10%, or any other amount acceptable to keep rechargeable batteries “topped off” and running for long periods of time. In implanted medical device applications, a useful energy exchange may be any exchange that does not harm the patient but that extends the life of a battery or wakes up a sensor or monitor or stimulator. In such applications, 100 mW of power or less may be useful. In distributed sensing applications, power transfer of microwatts may be useful, and transfer efficiencies may be well below 1%.

A useful energy exchange for wireless energy transfer in a powering or recharging application may be efficient, highly efficient, or efficient enough, as long as the wasted energy levels, heat dissipation, and associated field strengths are within tolerable limits and are balanced appropriately with related factors such as cost, weight, size, and the like.

The resonators may be referred to as source resonators, device resonators, first resonators, second resonators, repeater resonators, and the like. Implementations may include three (3) or more resonators. For example, a single source resonator may transfer energy to multiple device resonators or multiple devices. Energy may be transferred from a first device to a second, and then from the second device to the third, and so forth. Multiple sources may transfer energy to a single device or to multiple devices connected to a single device resonator or to multiple devices connected to multiple device resonators. Resonators may serve alternately or simultaneously as sources, devices, and/or they may be used to relay power from a source in one location to a device in another location. Intermediate electromagnetic resonators may be used to extend the distance range of wireless energy transfer systems and/or to generate areas of concentrated magnetic near-fields. Multiple resonators may be daisy-chained together, exchanging energy over extended distances and with a wide range of sources and devices. For example, a source resonator may transfer power to a device resonator via several repeater resonators. Energy from a source may be transferred to a first repeater resonator, the first repeater resonator may transfer the power to a second repeater resonator and the second to a third and so on until the final repeater resonator transfer its energy to a device resonator. In this respect the range or distance of wireless energy transfer may be extended and/or tailored by adding repeater resonators. High power levels may be split between multiple sources, transferred to multiple devices and recombined at a distant location.

The resonators may be designed sing coupled mode theory models, circuit models, electromagnetic field models, and the like. The resonators may be designed to have tunable characteristic sizes. The resonators may be designed to handle different power levels. In exemplary embodiments, high power resonators may require larger conductors and higher current or voltage rated components than lower power resonators.

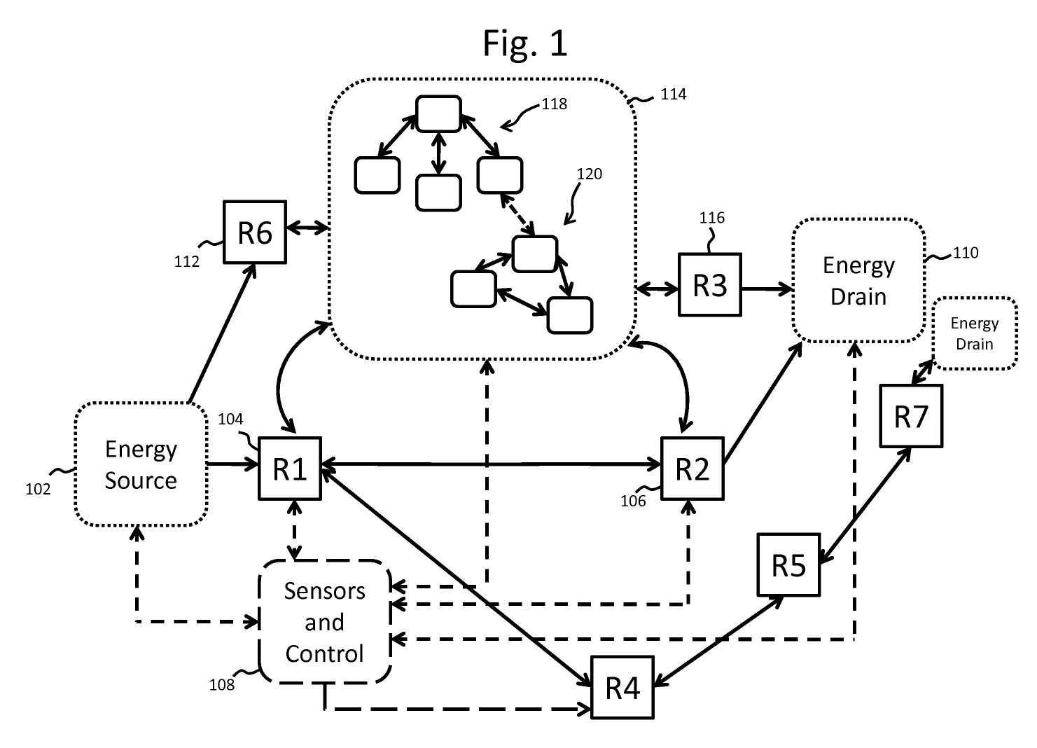

FIG. 1 shows a diagram of exemplary configurations and arrangements of a wireless energy transfer system. A wireless energy transfer system may include at least one source resonator (R1) 104 (optionally R6, 112) coupled to an energy source 102 and optionally a sensor and control unit 108. The energy source may be a source of any type of energy capable of being converted into electrical energy that may be used to drive the source resonator 104. The energy source may be a battery, a solar panel, the electrical mains, a wind or water turbine, an electromagnetic resonator, a generator, and the like. The electrical energy used to drive the magnetic resonator is converted into oscillating magnetic fields by the resonator. The oscillating magnetic fields may be captured by other resonators which may be device resonators (R2) 106, (R3) 116 that are optionally coupled to an energy drain 110. The oscillating fields may be optionally coupled to repeater resonators (R4, R5) that are configured to extend or tailor the wireless energy transfer region. Device resonators may capture the magnetic fields in the vicinity of source resonator(s), repeater resonators and other device resonators and convert them into electrical energy that may be used by an energy drain. The energy drain 110 may be an electrical, electronic, mechanical or chemical device and the like configured to receive electrical energy. Repeater resonators may capture magnetic fields in the vicinity of source, device and repeater resonator(s) and may pass the energy on to other resonators.

A wireless energy transfer system may comprise a single source resonator 104 coupled to an energy source 102 and a single device resonator 106 coupled to an energy drain 110. In embodiments a wireless energy transfer system may comprise multiple source resonators coupled to one or more energy sources and may comprise multiple device resonators coupled to one or more energy drains.

In embodiments the energy may be transferred directly between a source resonator 104 and a device resonator 106. In other embodiments the energy may be transferred from one or more source resonators 104, 112 to one or more device resonators 106, 116 via any number of intermediate resonators which may be device resonators, source resonators, repeater resonators, and the like. Energy may be transferred via a network or arrangement of resonators 114 that may include subnetworks 118, 120 arranged in any combination of topologies such as token ring, mesh, ad hoc, and the like.

In embodiments the wireless energy transfer system may comprise a centralized sensing and control system 108. In embodiments parameters of the resonators, energy sources, energy drains, network topologies, operating parameters, etc. may be monitored and adjusted from a control processor to meet specific operating parameters of the system. A central control processor may adjust parameters of individual components of the system to optimize global energy transfer efficiency, to optimize the amount of power transferred, and the like. Other embodiments may be designed to have a substantially distributed sensing and control system. Sensing and control may be incorporated into each resonator or group of resonators, energy sources, energy drains, and the like and may be configured to adjust the parameters of the individual components in the group to maximize the power delivered, to maximize energy transfer efficiency in that group and the like.

In embodiments, components of the wireless energy transfer system may have wireless or wired data communication links to other components such as devices, sources, repeaters, power sources, resonators, and the like and may transmit or receive data that can be used to enable the distributed or centralized sensing and control. A wireless communication channel may be separate from the wireless energy transfer channel, or it may be the same. In one embodiment the resonators used for power exchange may also be used to exchange information. In some cases, information may be exchanged by modulating a component in a source or device circuit and sensing that change with port parameter or other monitoring equipment. Resonators may signal each other by tuning, changing, varying, dithering, and the like, the resonator parameters such as the impedance of the resonators which may affect the reflected impedance of other resonators in the system. The systems and methods described herein may enable the simultaneous transmission of power and communication signals between resonators in wireless power transmission systems, or it may enable the transmission of power and communication signals during different time periods or a different frequencies using the same magnetic fields that are used during the wire energy transfer. In other embodiments wireless communication may be enabled with a separate wireless communication channel such as WiFi, Bluetooth, Infrared, and the like.

In embodiments, a wireless energy transfer system may include multiple resonators and overall system performance may be improved by control of various elements in the system. For example, devices with lower power requirements may tune their resonant frequency away from the resonant frequency of a high-power source that supplies power to devices with higher power requirements. In this way, low and high power devices may safely operate or charge from a single high power source. In addition, multiple devices in a charging zone may find the power available to them regulated according to any of a variety of consumption control algorithms such as First-Come-First-Serve, Best Effort, Guaranteed Power, etc. The power consumption algorithms may be hierarchical in nature, giving priority to certain users or types of devices, or it may support any number of users by equally sharing the power that is available in the source. Power may be shared by any of the multiplexing techniques described in this disclosure.

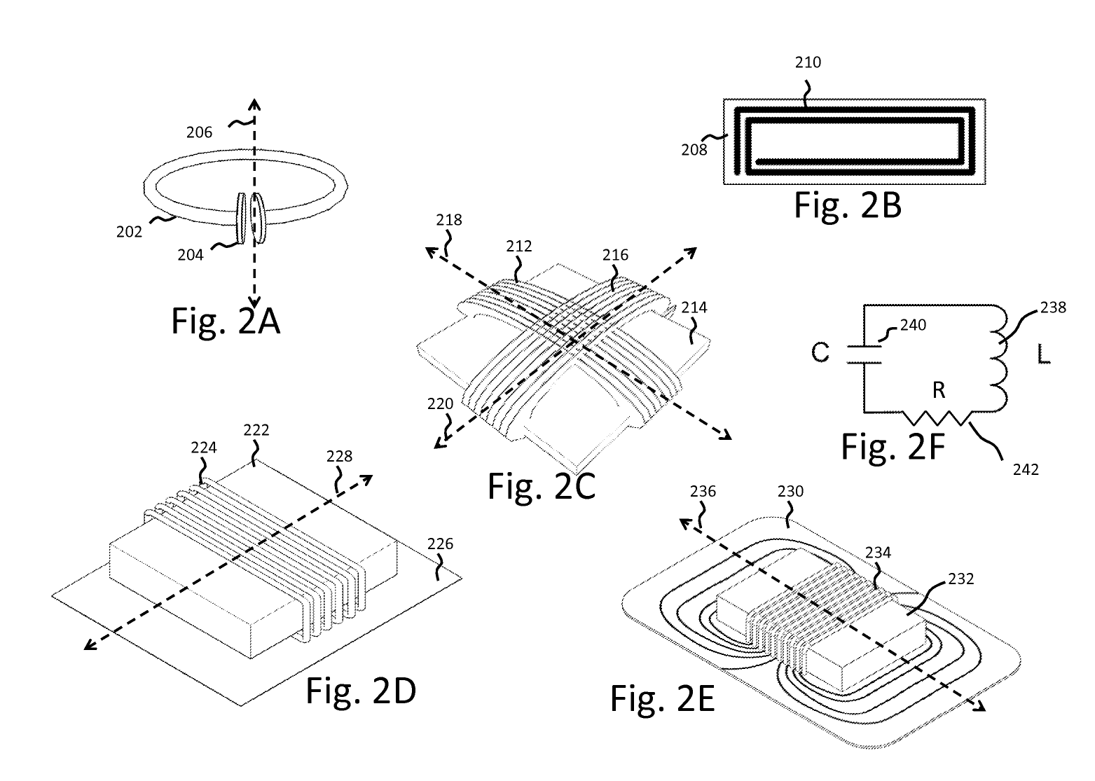

In embodiments electromagnetic resonators may be realized or implemented using a combination of shapes, structures, and configurations. Electromagnetic resonators may include an inductive element, a distributed inductance, or a combination of inductances with a total inductance, L, and a capacitive element, a distributed capacitance, or a combination of capacitances, with a total capacitance C. A minimal circuit model of an electromagnetic resonator comprising capacitance, inductance and resistance, is shown in FIG. 2F. The resonator may include an inductive element 238 and a capacitive element 240. Provided with initial energy, such as electric field energy stored in the capacitor 240, the system will oscillate as the capacitor discharges transferring energy into magnetic field energy stored in the inductor 238 which in turn transfers energy back into electric field energy stored in the capacitor 240. Intrinsic losses in these electromagnetic resonators include losses due to resistance in the inductive and capacitive elements and to radiation losses, and are represented by the resistor. R, 242 in FIG. 2F.

FIG. 2A shows a simplified drawing of an exemplary magnetic resonator structure. The magnetic resonator may include a loop of conductor acting as an inductive element 202 and a capacitive element 204 at the ends of the conductor loop. The inductor 202 and capacitor 204 of an electromagnetic resonator may be bulk circuit elements, or the inductance and capacitance may be distributed and may result from the way the conductors are formed, shaped, or positioned, in the structure.

For example, the inductor 202 may be realized by shaping a conductor to enclose a surface area, as shown in FIG. 2A. This type of resonator may be referred to as a capacitively-loaded loop inductor. Note that we may use the terms “loop” or “coil” to indicate generally a conducting structure (wire, tube, strip, etc.), enclosing a surface of any shape and dimension, with any number of turns. In FIG. 2A, the enclosed surface area is circular, but the surface may be any of a wide variety of other shapes and sizes and may be designed to achieve certain system performance specifications. In embodiments the inductance may be may be realized using inductor elements, distributed inductance, networks, arrays, series and parallel combinations of inductors and inductances, and the like. The inductance may be fixed or variable and may be used to vary impedance matching as well as resonant frequency operating conditions.

There are a variety of ways to realize the capacitance required to achieve the desired resonant frequency for a resonator structure. Capacitor plates 204 may be formed and utilized as shown in FIG. 2A, or the capacitance may be distributed and be realized between adjacent windings of a multi-loop conductor. The capacitance may be realized using capacitor elements, distributed capacitance, networks, arrays, series and parallel combinations of capacitances, and the like. The capacitance may be fixed or variable and may be used to vary impedance matching as well as resonant frequency operating conditions.

The inductive elements used in magnetic resonators may contain more than one loop and may spiral inward or outward or up or down or in some combination of directions. In general, the magnetic resonators may have a variety of shapes, sizes and number of turns and they may be composed of a variety of conducing materials. The conductor 210, for example, may be a wire, a Litz wire, a ribbon, a pipe, a trace farmed from conducting ink, paint, gels, and the like or from single or multiple traces printed on a circuit board. An exemplary embodiment of a trace pattern on a substrate 208 forming inductive loops is depicted in FIG. 2B.

In embodiments the inductive elements may be formed using magnetic materials of any size, shape thickness, and the like, and of materials with a wide range of permeability and loss values. These magnetic materials may be solid blocks, they may enclose hollow volumes, they may be formed from many smaller pieces of magnetic material tiled and or stacked together, and they may be integrated with conduction sheets or enclosures made from highly conducting materials. Conductors may be wrapped around the magnetic materials to generate the magnetic field. These conductors may be wrapped around one or more than one axis of the structure. Multiple conductors may be wrapped around the magnetic materials and combined in parallel, or in series, or via a switch to form customized near-field patterns and/or to orient the dipole moment of the structure. Examples of resonators comprising magnetic material are depicted in FIGS. 2C, 2D, 2E. In FIG. 2D the resonator comprises loops of conductor 224 wrapped around a core of magnetic material 222 creating a structure that has a magnetic dipole moment 228 that is parallel to the axis of hie loops of the conductor 224. The resonator may comprise multiple loops of conductor 216, 212 wrapped in orthogonal directions around the magnetic material 214 forming a resonator with a magnetic dipole moment 218, 220 that may be oriented in more than one direction as depicted in FIG. 2C, depending on how the conductors are driven.

An electromagnetic resonator may have a characteristic, natural, or resonant frequency determined by its physical properties. This resonant frequency is the frequency at which the energy stored by the resonator oscillates between that stored by the electric field, W_{E}, (W_{E}=q²/2C, where q is the charge on the capacitor, C) and that stored by the magnetic field. W_{B}, (W_{B}=Li²/2, where i is the current through the inductor, L) of the resonator. The frequency at which this energy is exchanged may be called the characteristic frequency, the natural frequency, or the resonant frequency of the resonator, and is given by ω,

$$ω = 2 π f = \sqrt{\frac{1}{LC}} .$$

The resonant frequency of the resonator may be changed by tuning the inductance, L, and/or the capacitance, C, of the resonator. In one embodiment system parameters are dynamically adjustable or tunable to achieve as close as possible to optimal operating conditions. However, based on the discussion above, efficient enough energy exchange may be realized even if some system parameters are not variable or components are not capable of dynamic adjustment.

In embodiments a resonator may comprise an inductive element coupled to more than one capacitor arranged in a network of capacitors and circuit elements. In embodiments the coupled network of capacitors and circuit elements may be used to define more than one resonant frequency of the resonator. In embodiments a resonator may be resonant, or partially resonant, at more than one frequency.

In embodiments, a wireless power source may comprise of at least one resonator coil coupled to a power supply, which may the a switching amplifier, such as a class-D amplifier or a class-E amplifier or a combination thereof. In this case, the resonator coil is effectively a power load to the power supply. In embodiments, a wireless power device may comprise of at least one resonator coil coupled to a power load, which may be a switching rectifier, such as a class-D rectifier or a class-E rectifier or a combination thereof. In this case, the resonator coil is effectively a power supply for the power load, and the impedance of the load directly relates also to the work-drainage rate of the load from the resonator coil. The efficiency of power transmission between a power supply and a power load may be impacted by how closely matched the output impedance of the power source is to the input impedance of the load. Power may be delivered to the load at a maximum possible efficiency, when the input impedance of the load is equal to the complex conjugate of the internal impedance of the power supply. Designing the power supply or power load impedance to obtain a maximum power transmission efficiency is often called “impedance matching”, and may also referred to as optimizing the ratio of useful-to-lost powers in the system. Impedance matching may be performed by adding networks or sets of elements such as capacitors, inductors, transformers, switches, resistors, and the like, to form impedance matching networks between a power supply and a power load. In embodiments, mechanical adjustments and changes in element positioning may be used to achieve impedance matching. For varying loads, the impedance matching network may include variable components that are dynamically adjusted to ensure that the impedance at the power supply terminals looking towards the load and the characteristic impedance of the power supply remain substantially complex conjugates of each other, even in dynamic environments and operating scenarios.

In embodiments, impedance matching may be accomplished by tuning the duty cycle, and/or the phase, and/or the frequency of the driving signal of the power supply or by timing a physical component within the power supply, such as a capacitor. Such a tuning mechanism may be advantageous because it may allow impedance matching between a power supply and a load without the use of a tunable impedance matching network, or with a simplified tunable impedance matching network, such as one that has fewer tunable components for example. In embodiments, tuning the duty cycle, and/or frequency, and/or phase of the driving signal to a power supply may yield a dynamic impedance matching system with an extended tuning range or precision, with higher power, voltage and/or current capabilities, with faster electronic control, with fewer external components, and the like.

In some wireless energy transfer systems the parameters of the resonator such as the inductance may be affected by environmental conditions such as surrounding objects, temperature, orientation, number and position of other resonators and the like. Changes in operating parameters of the resonators may change certain system parameters such as the efficiency of transferred power in the wireless energy transfer. For example, high-conductivity materials located near a resonator may shift the resonant frequency of a resonator and detune it from other resonant objects. In some embodiments, a resonator feedback mechanism is employed that corrects its frequency by changing a reactive element (e.g., an inductive element or capacitive element). In order to achieve acceptable matching conditions, at least some of the system parameters may need to be dynamically adjustable or tunable. All the system parameters may be dynamically adjustable or tunable to achieve approximately the optimal operating conditions. However, efficient enough energy exchange may be realized even if all or some system parameters are not variable. In some examples, at least some of the devices may not be dynamically adjusted. In some examples, at least some of the sources may not be dynamically adjusted. In some examples, at least some of the intermediate resonators may not be dynamically adjusted. In some examples, none of the system parameters may be dynamically adjusted.

In some embodiments changes in parameters of components may be mitigated by selecting components with characteristics that change in a complimentary or opposite way or direction when subjected to differences in operating environment or operating point. In embodiments, a system may be designed with components, such as capacitors, that have an opposite dependence or parameter fluctuation due to temperature, power levels, frequency, and the like. In some embodiments, the component values as a function of temperature may be stored in a look-up table in a system microcontroller and the reading from a temperature sensor may be used in the system control feedback loop to adjust other parameters to compensate for the temperature induced component value changes.

In some embodiments the changes in parameter values of components may be compensated with active tuning circuits comprising tunable components. Circuits that monitor the operating environment and operating point of components and system may be integrated in the design. The monitoring circuits may provide the signals necessary to active compensate for changes in parameters of components. For example, a temperature reading may be used to calculate expected changes in, or to indicate previously measured values of, capacitance of the system allowing compensation by switching in other capacitors or tuning capacitors to maintain die desired capacitance over a range of temperatures. In embodiments, the RF amplifier switching waveforms may be adjusted to compensate for component value or load changes in the system. In some embodiments die changes in parameters of components may be compensated with active cooling, heating, active environment conditioning, and the like.

The parameter measurement circuitry may measure or monitor certain power, voltage, and current, signals in the system, and processors or control circuits may adjust certain settings or operating parameters based on those measurements. In addition the magnitude and phase of voltage and current signals, and the magnitude of the power signals, throughout the system may be accessed to measure or monitor the system performance. The measured signals referred to throughout this disclosure may be any combination of port parameter signals, as well as voltage signals, current signals, power signals, temperatures signals and the like. These parameters may be measured using analog or digital techniques, they may be sampled and processed, and they may be digitized or converted using a number of known analog and digital processing techniques. In embodiments, preset values of certain measured quantities may be loaded in a system controller or memory location and used in various feedback and control loops. In embodiments, any combination of measured, monitored, and/or preset signals may be used in feedback circuits or systems to control the operation of the resonators and/or the system.

Adjustment algorithms may be used to adjust the frequency, Q, and/or impedance of the magnetic resonators. The algorithms may take as inputs reference signals related to the degree of deviation from a desired operating point for the system and may output correction or control signals related to that deviation that control variable or tunable elements of the system to bring the system back towards the desired operating point or points. The reference signals for the magnetic resonators may be acquired while the resonators are exchanging power in a wireless power transmission system, or they may be switched out of the circuit during system operation. Corrections to the system may be applied or performed continuously, periodically, upon a threshold crossing, digitally, using analog methods, and the like.

In embodiment, lossy extraneous materials and objects may introduce potential reductions in efficiencies by absorbing the magnetic and/or electric energy of the resonators of the wireless power transmission system. Those impacts may be mitigated in various embodiments by positioning resonators to minimize the effects of the loss extraneous materials and objects and by placing structural field shaping elements (e.g., conductive structures, plates and sheets, magnetic material structures, plates and sheets, and combinations thereof) to minimize their effect.

One way to reduce the impact of lossy materials on a resonator is to use high-conductivity materials, magnetic materials, or combinations thereof to shape the resonator fields such that they avoid the lossy objects. In an exemplary embodiment, a layered structure of high-conductivity material and magnetic material may tailor, shape, direct, reorient, etc. the resonator's electromagnetic fields so that they avoid lossy objects in their vicinity by deflecting the fields. FIG. 2D shows a top view of a resonator with a sheet of conductor 226 below the magnetic material that may used to tailor the fields of the resonator so that they avoid lossy objects that may be below the sheet of conductor 226. The layer or sheet of good 226 conductor may comprise any high conductivity materials such as copper, silver, aluminum, as may be most appropriate for a given application. In certain embodiments, the layer or sheet of good conductor is thicker than the skin depth of the conductor at the resonator operating frequency. The conductor sheet may be preferably larger than the size of the resonator, extending beyond the physical extent of the resonator.

In environments and systems where the amount of power being transmitted could present a safety hazard to a person or animal that may intrude into the active field volume, safety measures may be included in the system. In embodiments where power levels require particularized safety measures, the packaging, structure, materials, and the like of the resonators may be designed to provide a spacing or “keep away” zone from the conducting loops in the magnetic resonator. To provide further protection, high-Q resonators and power and control circuitry may be located in enclosures that confine high voltages or currents to within the enclosure, that protect the resonators and electrical components from weather, moisture, sand, dust, and other external elements, as well as from impacts, vibrations, scrapes, explosions, and other types of mechanical shock. Such enclosures call for attention to various factors such as thermal dissipation to maintain an acceptable operating temperature range for the electrical components and the resonator. In embodiments, enclosure may be constructed of non-lossy materials such as composites, plastics, wood, concrete, and the like and may be used to provide a minimum distance from lossy objects to the resonator components. A minimum separation distance from lossy objects or environments which may include metal objects, salt water, oil and the like, may improve the efficiency of wireless energy transfer. In embodiments, a “keep away” zone may be used to increase the perturbed Q of a resonator or system of resonators. In embodiments a minimum separation distance may provide for a more reliable or more constant operating parameters of the resonators.

In embodiments, resonators and their respective sensor and control circuitry may have various levels of integration with other electronic and control systems and subsystems. In some embodiments the power and control circuitry and the device resonators are completely separate modules or enclosures with minimal intergration to existing systems, providing a power output and a control and diagnostics interface. In some embodiments a device is configured to house a resonator and circuit assembly in a cavity inside the enclosure, or integrated into the housing or enclosure of the device.

Example Resonator Circuitry

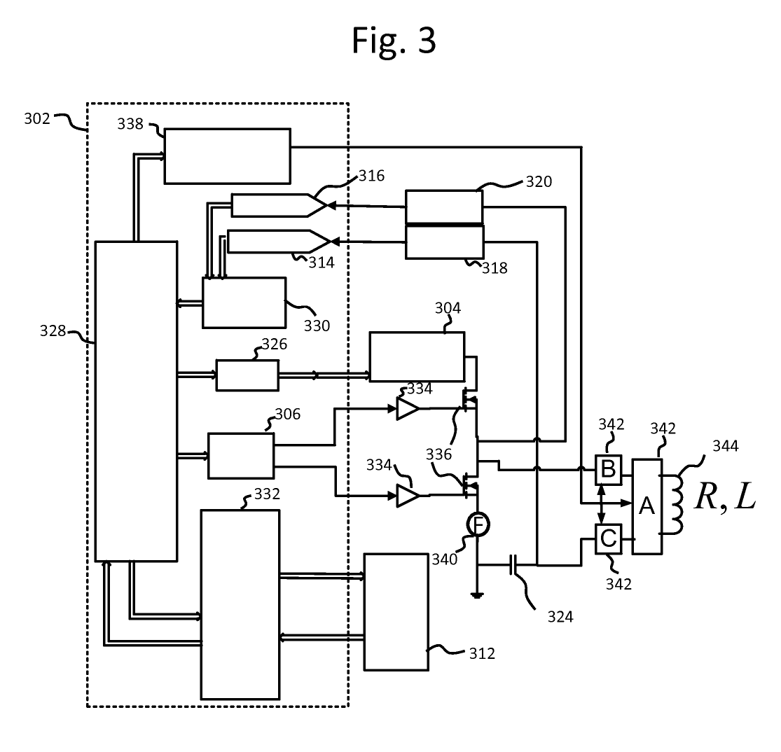

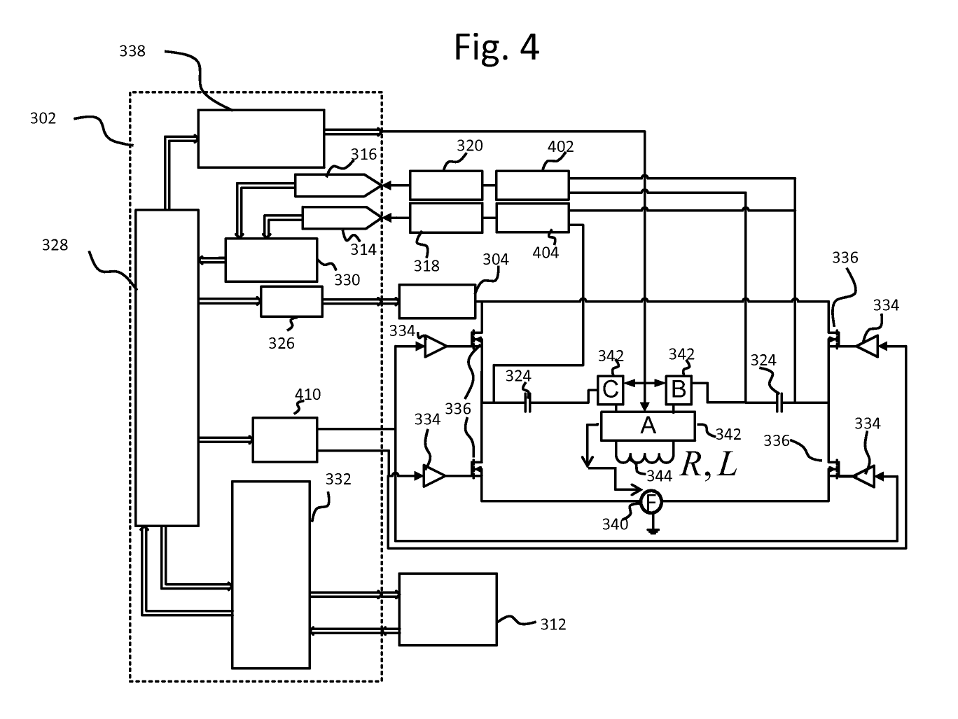

FIGS. 3 and 4 show high level block diagrams depicting power generation, monitoring, and control components for exemplary sources of a wireless energy transfer system. FIG. 3 is a block diagram of a source comprising a half-bridge switching power amplifier and some of the associated measurement, tuning, and control circuitry. FIG. 4 is a block diagram of a source comprising a full-bridge switching amplifier and some of the associated measurement, tuning, and control circuitry.

The half bridge system topology depicted in FIG. 3 may comprise a processing unit that executes a control algorithm 328. The processing unit executing a control algorithm 328 may be a microcontroller, an application specific circuit, a field programmable gate array, a processor, a digital signal processor, and the like. The processing unit may be a single device or it may be a network of devices. The control algorithm may run on any portion of the processing unit. The algorithm may be customized for certain applications and may comprise a combination of analog and digital circuits and signals. The master algorithm may measure and adjust voltage signals and levels, current signals and levels, signal phases, digital count settings, and the like.

The system may comprise an optional so source/device and/or source/other resonator communication controller 332 coupled to wireless communication circuitry 312. The optional source/device and/or source/other resonator communication controller 332 may be part of the same processing unit that executes the master control algorithm, it may a part or a circuit within a microcontroller 302, it may be external to the wireless power transmission modules, it may be substantially similar to communication controllers used in wire powered or battery powered applications but adapted to include some new or different functionality to enhance or support wireless power transmission.

The system may comprise a PWM generator 306 coupled to at least two transistor gate drivers 334 and may be controlled by the control algorithm. The two transistor gate drivers 334 may be coupled directly or via gate drive transformers to two power transistors 336 that drive the source resonator coil 344 through impedance matching network components 342. The power transistors 336 may be coupled and powered with an adjustable DC supply 304 and the adjustable DC supply 304 may be controlled by a variable bus voltage, Vbus. The Vbus controller may be controlled by the control algorithm 328 and may be part of, or integrated into, a microcontroller 302 or other integrated circuits. The Vbus controller 326 may control the voltage output of an adjustable DC supply 304 which may be used to control power output of the amplifier and power delivered to the resonator coil 344.

The system may comprise sensing and measurement circuitry including signal filtering and buffering circuits 318, 320 that may shape, modify, filter, process, buffer, and the like, signals prior to their input to processors and/or converters such as analog to digital converters (ADC) 314, 316, for example. The processors and converters such as ADCs 314, 316 may be integrated into a microcontroller 302 or may be separate circuits that may be coupled to a processing core 330. Based on measured signals, the control algorithm 328 may generate, limit, initiate, extinguish, control, adjust, or modify the operation of any of the PWM generator 306, the communication controller 332, the Vbus control 326, the source impedance matching controller 338, the filter/buffering elements, 318, 320, the converters, 314, 316, the resonator coil 344, and may be part of, or integrated into, a microcontroller 302 or a separate circuit. The impedance matching networks 342 and resonator coils 344 may include electrically controllable, variable, or tunable components such as capacitors, switches, inductors, and the like, as described herein, and these components may have their component values or operating points adjusted according to signals received from the source impedance matching controller 338. Components may be tuned to adjust the operation and characteristics of the resonator including the power delivered to and by the resonator, the resonant frequency of the resonator, the impedance of the resonator, the Q of the resonator, and any other coupled systems, and the like. The resonator may be any type or structure resonator described herein including a capacitively loaded loop resonator, a planer resonator comprising a magnetic material or any combination thereof.

The full bridge system topology depicted in FIG. 4 may comprise a processing unit that executes a master control algorithm 328. The processing unit executing the control algorithm 328 may be a microcontroller, an application specific circuit, a field programmable gate array, a processor, a digital signal processor, and the like. The system may comprise a source/device and/or source/other resonator communication controller 332 coupled to wireless communication circuitry 312. The source/device and/or source/other resonator communication controller 332 may be part of the same processing unit that executes that master control algorithm. It may a part or a circuit within a microcontroller 302, it may be external to the wireless power transmission modules, it may be substantially similar to communication controllers used in wire powered or battery powered applications but adapted to include some new or different functionality to enhance or support wireless power transmission.

The system may comprise a PWM generator 410 with at least two outputs coupled to at least four transistor gate drivers 334 that may be controlled by signals generated in a master control algorithm. The four transistor gate drivers 334 may be coupled to four power transistors 336 directly or via gate drive transformers that may drive the source resonator coil 344 through impedance matching networks 342. The power transistors 336 may be coupled and powered with an adjustable DC supply 304 and the adjustable DC supply 304 may be controlled by a Vbus controller 326 which may be controlled by a master control algorithm. The Vbus controller 326 may control the voltage output of the adjustable DC supply 304 which may be used to control power output of the amplifier and power delivered to the resonator coil 344.

The system may comprise sensing and measurement circuitry including signal filtering and buffering circuits 318, 320 and differential/single ended conversion circuitry 402, 404 that may shape, modify, filter, process, buffer, and the like, signals prior to being input to processors and/or converters such as analog to digital converters (ADC) 314, 316. The processors and/or converters such as ADC 314, 316 may be integrated into a microcontroller 302 or may be separate circuits that may be coupled to a processing core 330. Based on measured signals, the master control algorithm may generate, limit, initiate, extinguish, control, adjust, or modify the operation of any of the PWM generator 410, the communication controller 332, the Vbus controller 326, the source impedance matching controller 338, the filter/buffering elements, 318, 320, differential/single ended conversion circuitry 402, 404, the converters, 314, 316, the resonator coil 344, and may be part of or integrated into a microcontroller 302 or a separate circuit.

Impedance matching networks 342 ad resonator coils 344 may comprise electrically controllable, variable, or tunable components such as capacitors, switches, inductors, and the like, as described herein, and these components may have their component values or operating points adjusted according to signals received from the source impedance matching controller 338. Components may be tuned to enable tuning of the operation and characteristics of the resonator including the power delivered to and by the resonator, the resonant frequency of the resonator, the impedance of the resonator, the Q of the resonator, and any other coupled systems, and the like. The resonator may be any type or structure resonator described herein including a capacitively loaded loop resonator, a planar resonator comprising a magnetic material or any combination thereof.

Impedance matching networks may comprise fixed value components such as capacitors, inductors, and networks of components as described herein. Parts of the impedance matching networks, A, B and C, may comprise inductors, capacitors, transformers, and series and parallel combinations of such components, as described herein. In some embodiments, parts of the impedance matching networks A, B, and C, may be empty (short-circuited). In some embodiments, part B comprises a series combination of an inductor and a capacitor, and part C is empty.

The full bridge topology may allow operation, at higher output power levels using the same DC bus voltage as an equivalent half bridge amplifier. The half bridge exemplary topology of FIG. 3 may provide a single-ended drive signal, while the exemplary full bridge topology of FIG. 4 may provide a differential drive to the source resonator 308. The impedance matching topologies and components and the resonator structure may be different for the two systems, as discussed herein.

The exemplary systems depicted in FIGS. 3 and 4 may further include fault detection circuitry 340 that may be used to trigger the shutdown of the microcontroller in the source amplifier or to change or interrupt the operation of the amplifier. This protection circuitry may comprise a high speed comparator or comparators to monitor the amplifier return current, the amplifier bus voltage (Vbus) from the DC supply 304, the voltage across the source resonator 308 and/or the optional tuning board, or any other voltage or current signals that may cause damage to components in the system or may yield undesirable operating conditions. Preferred embodiments may depend on the potentially undesirable operating modes associated with different applications. In some embodiments, protection circuitry may not be implemented or circuits may not be populated. In some embodiments, system and component protection may be implemented as part of a master control algorithm and other system monitoring and control circuits. In embodiments, dedicated fault circuitry 340 may include an output (not shown) coupled to a master control algorithm 328 that may trigger a system shutdown, a reduction of the output power (e.g. reduction of Vbus), a change to the PWM generator, a change in the operating frequency, a change to a tuning element, or any other reasonable action that may be implemented by the control algorithm 328 to adjust the operating point mode, improve system performance, and/or provide protection.

As described herein, sources in wireless power transfer systems may use a measurement of the input impedance of the impedance matching network 342 driving source resonator coil 344 as an error or control signal for a system control loop that may be part of the master control algorithm. In exemplary embodiments, variations in any combination of three parameters may be used to time the wireless power source to compensate for changes in environmental conditions, for changes in coupling, for changes in device power demand, for changes in module, circuit, component or subsystem performance, for an increase or decrease in the number or sources, devices, or repeaters in the system, for user initiated changes, and the like. In exemplary embodiments, changes to the amplifier duty cycle, to the component values of the variable electrical components such as variable capacitors and inductors, and to the DC bus voltage may be used to change the operating point or operating range of the wireless source and improve some system operating value. The specifics of the control algorithms employed for different applications may vary depending on the desired system performance and behavior.

Impedance measurement circuitry such as described herein, and shown in FIGS. 3 and 4, may be implemented using two-channel simultaneous sampling ADCs and these ADCs may be integrated into a microcontroller chip or may be part of a separate circuit. Simultaneously sampling of the voltage and current signals at the input to a source resonator's impedance matching network and/or the source resonator, may yield the phase and magnitude information of the current and voltage signals and may be processed using known signal processing techniques to yield complex impedance parameters. In some embodiments, monitoring only the voltage signals or only the current signals may be sufficient.

The impedance measurements described herein may use direct sampling methods which may be relatively simpler than some other known sampling methods. In embodiments, measured voltage and current signals may be conditioned, filtered and scaled by filtering/buffering circuitry before being input to ADCs. In embodiments, the filter/buffering circuitry may be adjustable to work at a variety of signal levels and frequencies, and circuit parameters such as filter shapes and widths may be adjusted manually, electronically, automatically, in response to a control signal, by the master control algorithm, and the like. Exemplary embodiments of filter/buffering circuits are shown in FIGS. 3, 4, and 5.

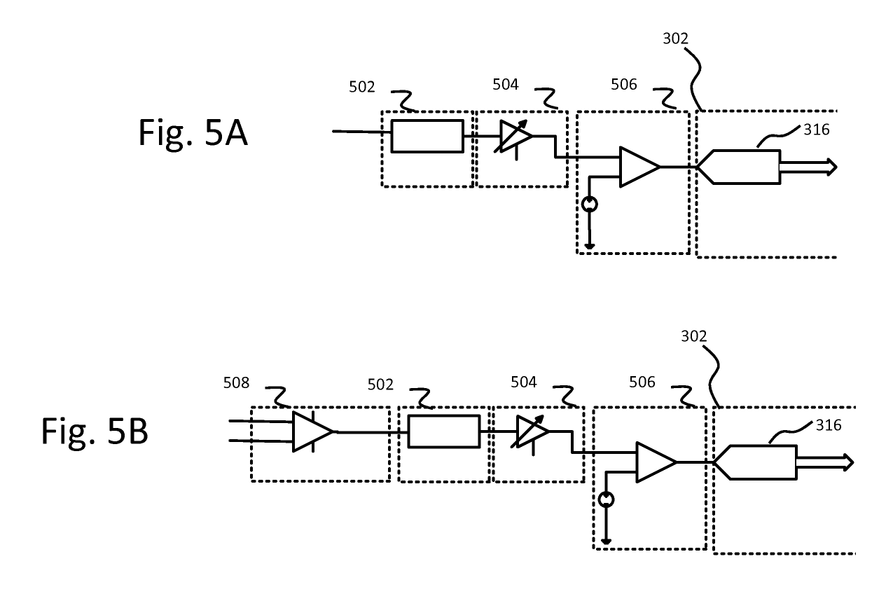

FIG. 5 shows more detailed views of exemplary circuit components that may be used in filter/buffering circuitry. In embodiments, and depending on the types of ADCs used in the system designs, single-ended amplifier topologies may reduce the complexity of the analog signal measurement paths used to characterize system, subsystem, module and/or component performance by eliminating the need for hardware to convert from differential to single-ended signal formats. In other implementations, differential signal formats may be preferable. The implementations shown in FIG. 5 are exemplary, and should not be construed to be the only possible way to implement the functionality described herein. Rather it should be understood that the analog signal path may employ components with different input requirements and hence may have different signal path architectures.

In both the single ended and differential amplifier topologies, the input current to the impedance matching networks 342 driving the resonator coils 344 may be obtained by measuring the voltage across a capacitor 324, or via a current sensor of some type. For the exemplary single-ended amplifier topology in FIG. 3, the current may be sensed on the ground return path from the impedance matching network 342. For the exemplary differential power amplifier depicted in FIG. 4, the input current to the impedance matching networks 342 driving the resonator coils 344 may be measured using a differential amplifier across the terminals of a capacitor 324 or via a current sensor of some type. In the differential topology of FIG. 4, the capacitor 324 may be duplicated at the negative output terminal of the source power amplifier.

In both topologies, after single ended signals representing the input voltage and current to the source resonator and impedance matching network are obtained, the signals may be filtered 502 to obtain the desired portions of the signal waveforms. In embodiments, the signals may be filtered to obtain the fundamental component of the signals. In embodiments, the type of filtering performed, such as low pass, bandpass, notch, and the like, as well as the filter topology used, such as elliptical, Chebyshev, Butterworth, and the like, may depend on the specific requirements of the system. In some embodiments, no filtering will be required.

The voltage and current signals may be amplified by an optional amplifier 504. The gain of the optional amplifier 504 may be fixed or variable. The gain of the amplifier may be controlled manually, electronically, automatically, in response to a control signal, and the like. The gain of the amplifier may be adjusted in a feedback loop, in response to a control algorithm, by the master control algorithm, and the like. In embodiments, required performance specifications for the amplifier may depend on signal strength and desired measurement accuracy, and may be different for different application scenarios and control algorithms.

The measured analog signals may have a DC offset added to them, 506, which may be required to bring the signals into the input voltage range of the ADC which for some systems may be 0 to 3.3V. In some systems this stage may not be required, depending on the specifications of the particular ADC used.

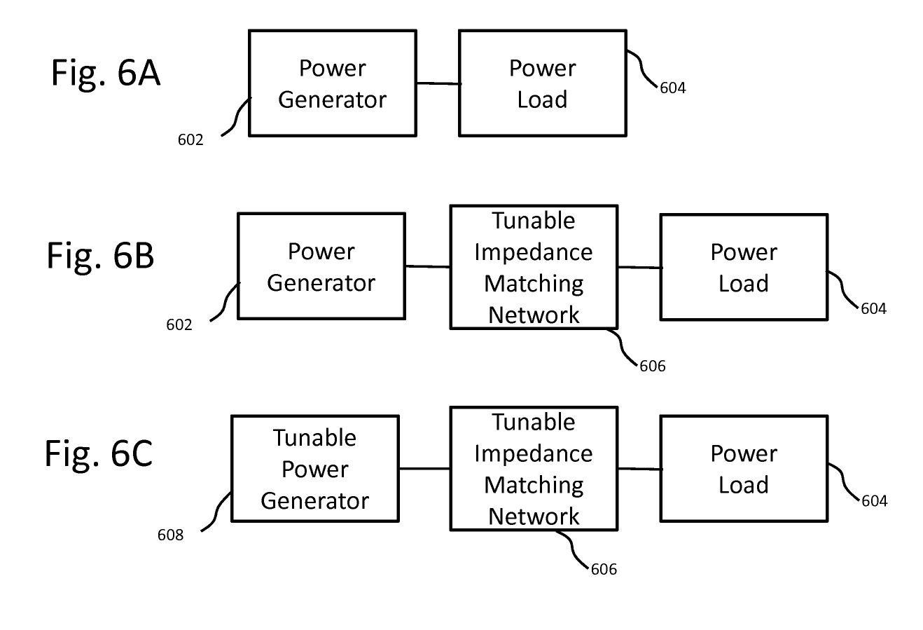

As described above, the efficiency of power transmission between a power generator and a power load may be impacted by how closely matched the output impedance of the generator is to the input impedance of the load. In an exemplary system as shown in FIG. 6A, power may be delivered to the load at a maximum possible efficiency, when the input impedance of the load 604 is equal to the complex conjugate of the internal impedance of the power generator or the power amplifier 602. Designing the generator or load impedance to obtain a high and/or maximum power transmission efficiency may be called “impedance matching”. Impedance matching may be performed by inserting appropriate networks or sets of elements such as capacitors, resistors, inductors, transformers, switches and the like, to form an impedance matching network 606, between a power generator 602 and a power load 604 as shown in FIG. 6B. In other embodiments, mechanical adjustments and changes in element positioning may be used to achieve impedance matching. As described above for varying loads, the impedance matching network 606 may include variable components that are dynamically adjusted to ensure that the impedance at the generator terminals looking towards the load and the characteristic impedance of the generator remain substantially complex conjugates of each other, even in dynamic environments and operating scenarios. In embodiments, dynamic impedance matching may be accomplished by tuning the duty cycle, and/or the phase, and/or the frequency of the driving signal of the power generator or by tuning a physical component within the power generator, such as a capacitor, as depicted in FIG. 6. Such a tuning mechanism may be advantageous because it may allow impedance matching between a power generator 608 and a load without the use of a tunable impedance matching network, or with a simplified tunable impedance matching network 606, such as one that has fewer tunable components for example. In embodiments, tuning the duty cycle, and/or frequency, and/or phase of the driving signal to a power generator may yield a dynamic impedance matching system with an extended tuning range or precision, with higher power, voltage and/or current capabilities, with faster electronic control, with fewer external components, and the like. The impedance matching methods, architectures, algorithms, protocols, circuits, measurements, controls, and the like, described below, may be useful in systems where power generators drive high-Q magnetic resonators and in high-Q wireless power transmission systems as described herein. In wireless power transfer systems a power generator may be a power amplifier driving a resonator, sometimes referred to as a source resonator, which may be a load to the power amplifier. In wireless power applications, it may be preferable to control the impedance matching between a power amplifier and a resonator load to control the efficiency of the power delivery from the power amplifier to the resonator. The impedance matching may be accomplished, or accomplished in part, by tuning or adjusting the duty cycle, and/or the phase, and/or the frequency of the driving signal of the power amplifier that drives the resonator.

Efficiency of Switching Amplifiers

Switching amplifiers, such as class D, E, F amplifiers, and the like or any combinations thereof, deliver power to a load at a maximum efficiency when no power is dissipated on the switching elements of the amplifier. This operating condition may be accomplished by designing the system so that the switching operations which are most critical (namely those that are most likely to lead to switching losses) are done when both the voltage across the switching element and the current through the switching element are zero. These conditions may be referred to as Zero Voltage Switching (ZVS) and Zero Current Switching (ZCS) conditions respectively. When an amplifier operates at ZVS and ZCS either the voltage across the switching element or the current through the switching element is zero and thus no power can be dissipated in the switch. Since a switching amplifier may convert DC (or very low frequency AC) power to AC power at a specific frequency or range of frequencies, a filer may be introduced before the load to prevent unwanted harmonics that may be generated by the switching process from reaching the load and being dissipated there. In embodiments, a switching amplifier may be designed to operate at maximum efficiency of power conversion, when connected to a resonant load, with a nontrivial quality factor (say Q>5), and of a specific impedance Zₒ*=Rₒ+jXₒ, which leads to simultaneous ZVS and ZCS. We define Zₒ=Rₒ−jXₒ as the characteristic impedance of the amplifier, so that achieving maximum power transmission efficiency is equivalent to impedance matching the resonant load to the characteristic impedance of the amplifier.

In a switching amplifier, the switching frequency of the switching elements, f_{switch}, wherein f_{switch}=ω/2π and the duty cycle, dc, of the ON switch-state duration of the switching elements may be the same for all switching elements of the amplifier. In this specification, we will use the term “class D” to denote both class D and class DE amplifiers, that is, switching amplifiers with dc<=50%.

The value of the characteristic impedance of the amplifier may depend on the operating frequency, the amplifier topology, and the switching sequence of the switching elements. In some embodiments, the switching amplifier may be a half-bridge topology and, an some embodiments, a full-bridge topology. In some embodiments, the switching amplifier may be class D and, in some embodiments, class E. In any of the above embodiments, assuming the elements of the bridge are symmetric, the characteristic impedance of the switching amplifier has the form

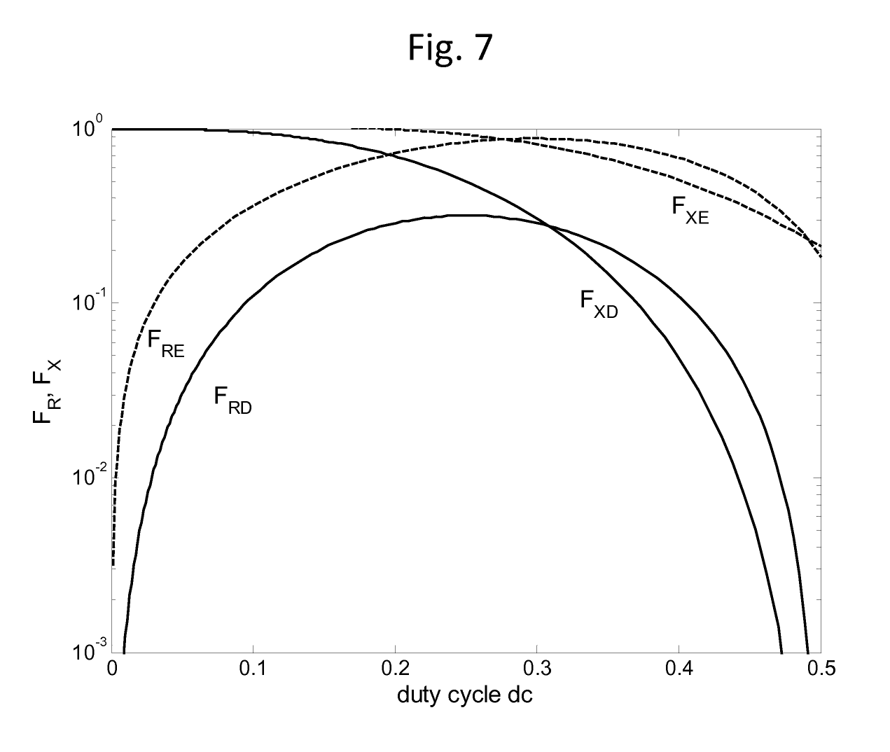

Rₒ=F_{R}(dc)/ωCₐ,Xₒ=F_{X}(dc)/ωCₐ, (1)

where dc is the duty cycle of the ON switch-state of the switching elements, the functions F_{R}(dc) and F_{X}(dc) are plotted in FIG. 7 (both for class D and E), ω is the frequency at which the switching elements are switched, and Cₐ=nₐC_{switch} where C_{switch} is the capacitance across each switch, including both the transistor output capacitance and also possible external capacitors placed in parallel with the switch, while nₐ=1 for a full bridge and nₐ=2 for a half bridge. For class D, one can also write the analytical expressions

F_{R}(dc)=sin²u/π,F_{X}(dc)=(u−sin u*cos u)/π, (2)

where u=π(1−2*dc), indicating that the characteristic impedance level of a class D amplifier decreases as the duty cycle, dc, increases towards 50%. For a class D amplifier operation with dc=50%, achieving ZVS and ZCS is possible only when the switching elements have practically no output capacitance (Cₐ=0) and the load is exactly on resonance (Xₒ=0), while Rₒ can be arbitrary.

Impedance Matching Networks

In applications, the driven load may have impedance that is very different from the characteristic impedance of the external driving circuit, to which it is connected. Furthermore, the driven load may not be a resonant network. An Impedance Matching Network (IMN) is a circuit network that may be connected before a load as in FIG. 6B, in order to regulate the impedance that is seen at the input of the network consisting of the IMN circuit and the load. An IMN circuit may typically achieve this regulation by creating a resonance close to the driving frequency. Since such an IMN circuit accomplishes all conditions needed to maximize the power transmission efficiency from the generator to the load (resonance and impedance matchinag—ZVS and ZCS for a switching amplifier), in embodiments, an IMN circuit may be used between the driving circuit and the load.

For an arrangement shown in FIG. 6B, let the input impedance of the network consisting of the Impedance Matching Network (IMN) circuit and the load (denoted together from now on as IMN+load) be Zₗ=Rₗ(ω)+jXₗ(ω). The impedance matching conditions of this network to the external circuit with characteristic impedance Zₒ=Rₒ−jXₒ are then Rₗ(ω)=Rₐ, Xₗ(ω)=Xₒ.

Methods for Tunable Impedance Matching of a Variable Load

In embodiments where the load may be variable, impedance matching between the load and the external riving circuit, such as a linear or switching power amplifier, may be achieved by using adjustable/tunable components in the IMN circuit that may be adjusted to match the varying load to the fixed characteristic impedance Zₒ of the external circuit (FIG. 6B). To match both the real and imaginary parts of the impedance two tunable/variable elements in the IMN circuit may be needed.

In embodiments, the load may be inductive (such as a resonator coil) with impedance R+jωL, so the two tunable elements in the IMN circuit may be two tunable capacitance networks or one tunable capacitance network and one tunable inductance network or one tunable capacitance network and one tunable mutual inductance network.

In embodiments where the load may be variable, the impedance matching between the load and the driving circuit, such as a linear or switching power amplifier, may be achieved by using adjustable/tunable components or parameters in the amplifier circuit that may be adjusted to match the characteristic impedance Zₒ of the amplifier to the varying (due to load variations) input impedance of the network consisting of the IMN circuit and the load (IMN+load), where the IMN circuit may also be tunable (FIG. 6C). To match both the real and imaginary parts of the impedance, at least two tunable/variable elements or parameters in the amplifier and the IMN circuit may be needed. The disclosed impedance matching method can reduce the required number of tunable/variable elements in the IMN circuit or even completely eliminate the requirement for tunable/variable elements in the IMN circuit. In some examples, one tunable element in the power amplifier and one tunable element in the IMN circuit may be used. In some examples, two tunable elements in the power amplifier and no tunable element in the IMN circuit may be used.

In embodiments, the tunable elements or parameters in the power amplifier may be the frequency, amplitude, phase, waveform, duty cycle and the like of the drive signals applied to transistors, switches, diodes and the like.

In embodiments, the power amplifier with tunable characteristic impedance may be a tunable switching amplifier of class D, E, F or any combinations thereof. Combining Equations (1) and (2), the impedance matching conditions for this network are

Rₗ(ω)=F_{R}(dc)/ωCₐ,Xₗ(ω)=F_{X}(dc)/ωCₐ (3).

In some examples of a tunable switching amplifier, one unable element may be the capacitance Cₐ, which may be tuned by tuning the external capacitors placed in parallel with the switching elements.

In some examples of a tunable switching amplifier, one tunable element may be the duty cycle dc of the ON switch-sate of the switching elements of the amplifier. Adjusting the duty cycle, dc, via Pulse Width Modulation (PWM) has been used in switching amplifiers to achieve output power control. In this specification, we disclose that PWM may also be used to achieve impedance matching, namely to satisfy Eq. (3), and thus maximize the amplifier efficiency.

In some examples of a tunable switching amplifier one tunable element may be the switching frequency, which is also the driving frequency of the IMN+load network and may be designed to be substantially close to the resonant frequency of the IMN+load network. Tuning the switching frequency may change the characteristic impedance of the amplifier and the impedance of the IMN+load network. The switching frequency of the amplifier may be tuned appropriately together with one more tunable parameters, so that Eq. (3) is satisfied.

A benefit of tuning the duty cycle and/or the driving frequency of the amplifier for dynamic impedance matching is that these parameters can be tuned electronically, quickly, and over a broad range. In contrast, for example, a tunable capacitor that can sustain a large voltage and has a large enough tunable range and quality factor may be expensive, slow or unavailable for with the necessary component specifications.

Examples of Methods for Tunable Impedance Matching of a Variable Load

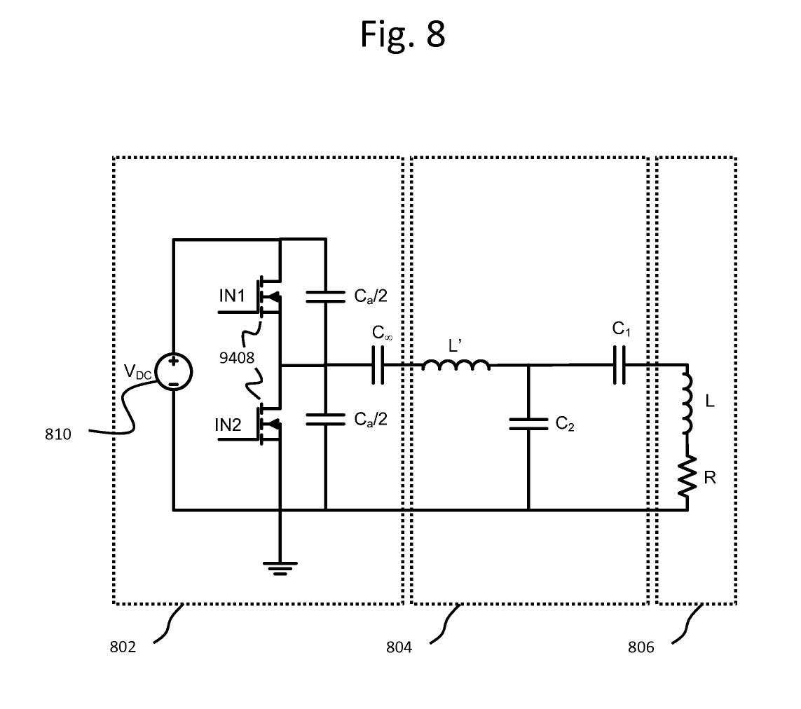

A simplified circuit diagram showing the circuit level structure of a class D power amplifier 802. Impedance matching network 804 and an inductive load 806 is shown in FIG. 8. The diagram shows the basic components of the system with the switching amplifier 804 comprising a power source 810, switching elements 808, and capacitors. The impedance matching network 804 comprising inductors and capacitors, and the load 86 modeled as an inductor and a resistor.

An exemplary embodiment of this inventive tuning scheme comprises a half-bridge class-D amplifier operating at switching frequency f and driving a low-loss inductive element R+jωL via an IMN, as shown in FIG. 8.

In some embodiments L′ may be tunable. L′ may be tuned by a variable tapping point on the inductor or by connecting a tunable capacitor in series or in parallel to the inductor. In some embodiments Cₐ may be tunable. For the half bridge topology, Cₐ may be tuned by varying either one or both capacitors C_{switch}, as only the parallel sum of these capacitors matters for the amplifier operation. For the full bridge topology, Cₐ may be tuned by varying either one, two, three or all capacitors C_{switch}, as only their combination (series sum of the two parallel sums associated with the two halves of the bridge) matters for the amplifier operation.

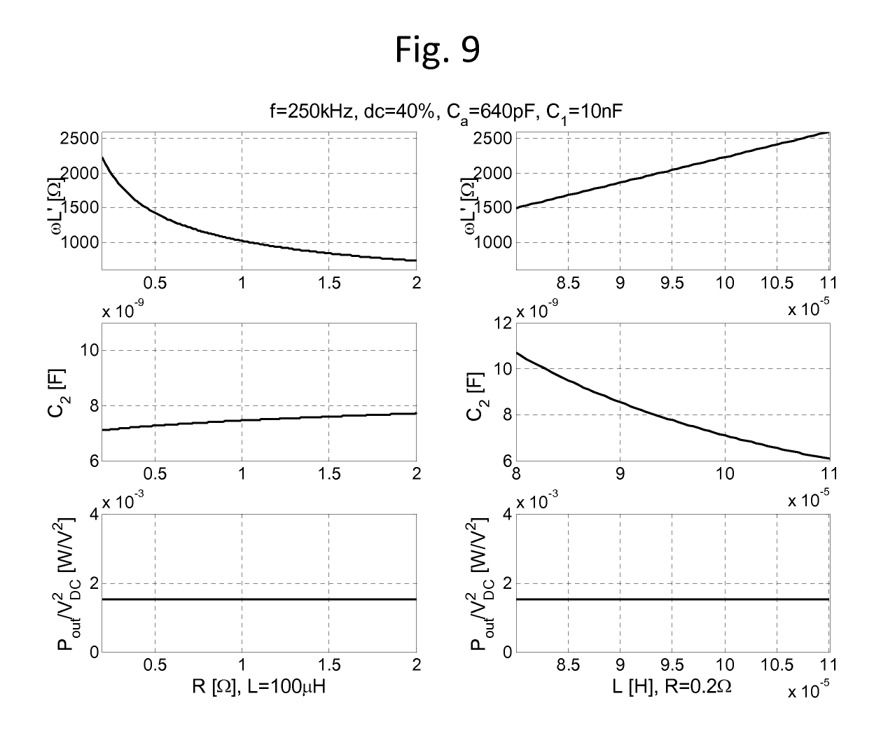

In some embodiments of tunable impedance matching, two of the components of the IMN may be tunable. In some embodiments, L′ and C₂ may be tuned. Then, FIG. 9 shows the values of the two tunable components needed to achieve impedance matching as functions of the varying R and L of the inductive element, and the associated variation of the output power (at given DC bus voltage) of the amplifier, for f=250 kHz, dc=40%, Cₐ=640 pF and C₁=10 nF. Since the IMN always adjusts to the fixed characteristic impedance of the amplifier, the output power is always constant as the inductive element is varying.

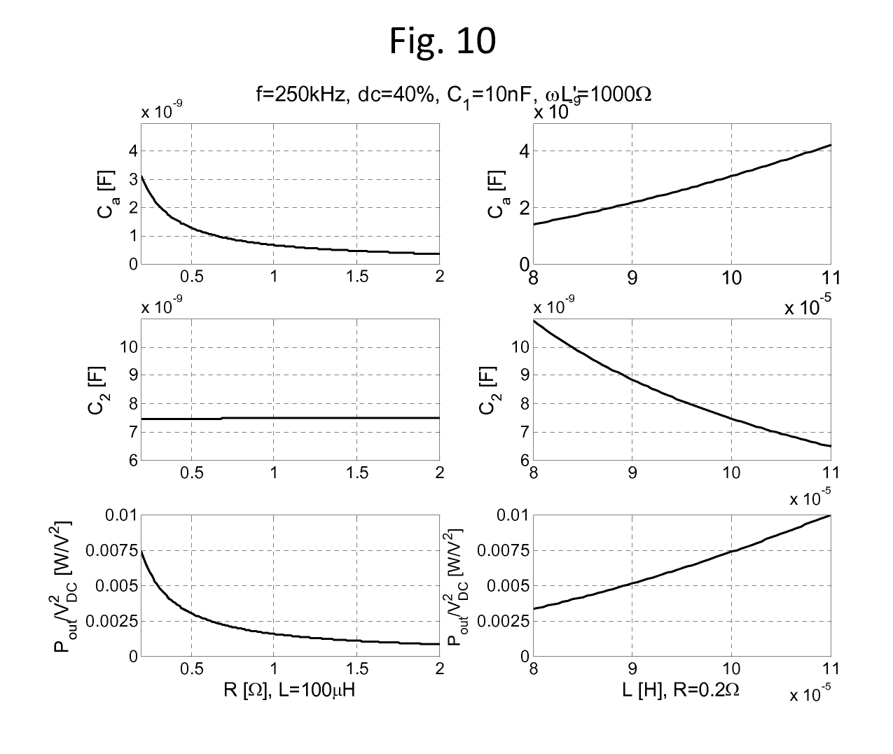

In some embodiments of tunable impedance matching, elements in the switching amplifier may also be tunable. In some embodiments the capacitance Cₐ along with the IMN capacitor C₂ may be tuned. Then, FIG. 10 shows the values of the two tunable components needed to achieve impedance matching as functions of the varying R and L of the inductive element, and the associated variation of the output power (at given DC bus voltage) of the amplifier for f=250 kHz, dc=40%. C₁=10 nF and ωL′=1000Ω. It can be inferred from FIG. 10 that C₂ needs to be tuned mainly in response to variations in L and that the output power decreases as R increases.

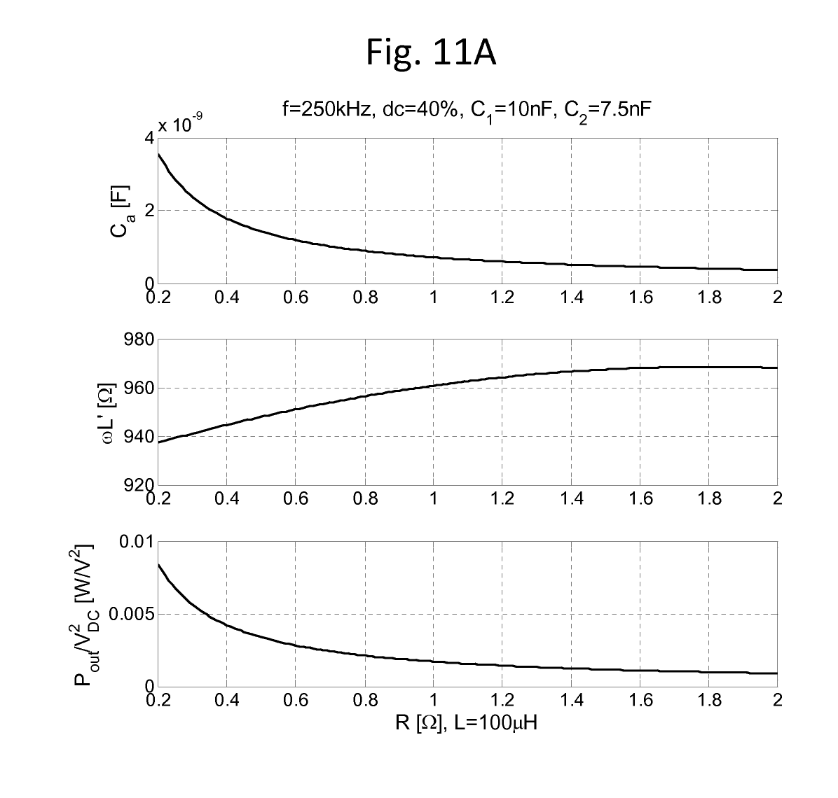

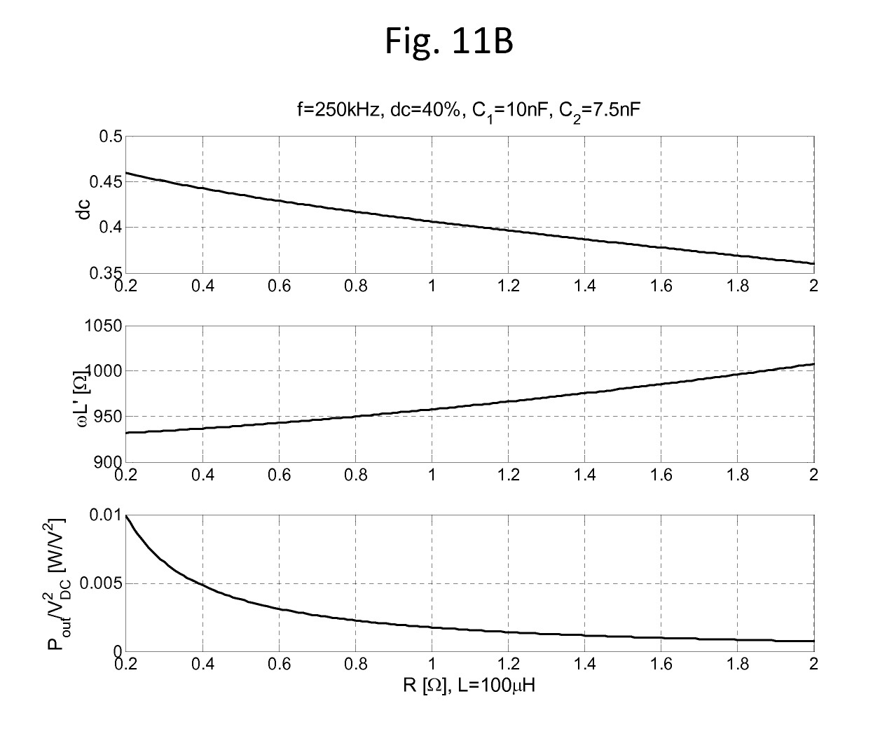

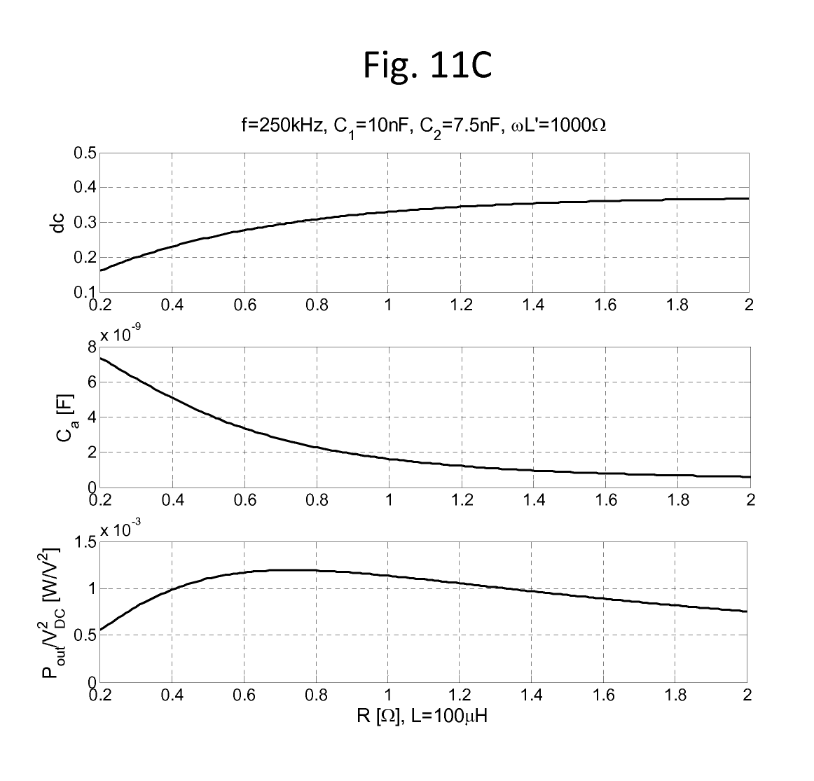

In some embodiments of tunable impedance matching, the duty cycle dc along with the IMN capacitor C₂ may be tuned. Then, FIG. 11 shows the values of the two tunable parameters needed to achieve impedance matching as functions of the varying R and L of the inductive element, and the associated variation of the output power (at given DC bus voltage) of the amplifier for f=250 kHz, Cₐ=640 pF, C₁=10 nF and ωL′=1000Ω. It can be inferred from FIG. 11 that C₂ needs to be tuned mainly in response to variations in L and that the output power decreases as R increases.

In some embodiments of tunable impedance matching, the capacitance Cₐ along with the IMN inductor L′ may be tuned. Then. FIG. 11A shows the values of the two tunable components needed to achieve impedance matching as functions of the varying R of the inductive element, and the associated variation of the output power (at given DC bus voltage) of the amplifier for f=250 kHz, dc=40%, C₁=10 nF and C₂=7.5 nF. It can be inferred from FIG. 11A that the output power decreases as R increases.

In some embodiments of tunable impedance matching, the duty cycle dc along with the IMN inductor L′ may be tuned. Then, FIG. 11B shows the values of the two tunable parameters needed to achieve impedance matching as functions of the varying R of the inductive element, and the associated variation of the output power (at given DC bus voltage) of the amplifier for f=250 kHz, Cₐ=640 pF, C₁=10 nF and C₂=7.5 nF as functions of the varying R of the inductive element. It can be inferred from FIG. 11B that the output power decreases as R increases.

In some embodiments of tunable impedance matching, only elements in the switching amplifier may be tunable with no tunable elements in the IMN. In some embodiments the duty cycle dc along with the capacitance Cₐ may be tuned. Then, FIG. 11C, shows the values of the two tunable parameters needed to achieve impedance matching as functions of the varying R of the inductive element, and the associated variation of the output power (at given DC bus voltage) of the amplifier for f=250 kHz, C₁10 nF, C₂=7.5 nF and ωL′=1000Ω. It can be inferred from FIG. 11C that the output power is a non-monotonic function of R. These embodiments may be able to achieve dynamic impedance matching when variations in L (and thus the resonant frequency) are modest.

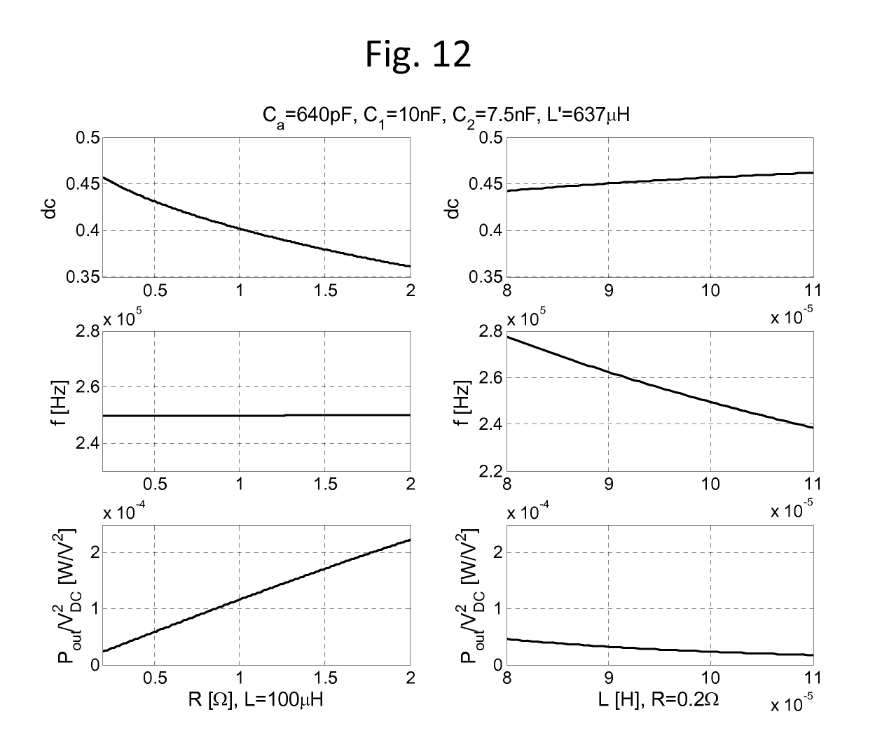

In some embodiments, dynamic impedance matching with fixed elements inside the IMN, also when L is varying greatly as explained earlier, may be achieved by varying the driving frequency of the external frequency f (e.g. the switching frequency of a switching amplifier) so that it follows the varying resonate frequency of the resonator. Using the switching frequency f and the switch duty cycle dc as the two variable parameters, full impedance matching can be achieved as R and L are varying without the need of any variable components. Then, FIG. 12 shows the values of the two tunable parameters needed to achieve impedance matching as functions of the varying R and L of the inductive element, and the associated variation of the output power (at given DC bus voltage) of the amplifier for Cₐ=640 pF. C₁=10 nF, C₂=7.5 nF and L′=637 μH. It can be interred from FIG. 12 that the frequency f needs to be tuned mainly in response to variations in L, as explained earlier.

Tunable Impedance Matching for Systems of Wireless Power Transmission

In applications of wireless power transfer the low-loss inductive element may be the coil of a source resonator coupled to one or more device resonators or other resonators, such as repeater resonators, for example. The impedance of the inductive element R+jωL may include the reflected impedances of the other resonators on the coil of the source resonator. Variations of R and L of the inductive element may occur due to external perturbations in the vicinity of the source resonator and/or the other resonators or thermal drift of components. Variations of R and L of the inductive element may also occur during normal use of the wireless power transmission system due to relative motion of the devices and other resonators with respect to the source. The relative motion of these devices and other resonators with respect to the source, or relative motion or position of other sources, may lead to varying coupling (and thus varying reflected impedances) of the devices to the source. Furthermore, variations of R and L of the inductive element may also occur during normal use of the wireless power transmission system due to changes within the other coupled resonators, such as changes in the power draw of their loads. All the methods and embodiments disclosed so far apply also this case in order to achieve dynamic impedance matching of this inductive element to the external circuit driving it.

To demonstrate the presently disclosed dynamic impedance matching methods for a wireless power transmission system, consider a source resonator including a low-loss source coil, which is inductively coupled to the device coil of a device resonator driving a resistive load.

In some embodiments, dynamic impedance matching may be achieved at the source circuit. In some embodiments, dynamic impedance matching may also be achieved at the device circuit. When full impedance matching is obtained (both at the source and the device), the effective resistance of the source inductive element (namely the resistance of the source coil Rₛ plus the reflected impedance from the device) is R=Rₛ\sqrt{1+U_{sd}²}, (Similarly the effective resistance of the device inductive element is R_{d}\sqrt{1+U_{sd}²}, where R_{d} is the resistance of the device coil.) Dynamic variation of the mutual inductance between the coils due to motion results in a dynamic variation of U_{sd}=ωM_{sd}/\sqrt{RₛR_{d}}. Therefore, when both source and device are dynamically tuned, the variation of mutual inductance is seen from the source circuit side as a variation in the source inductive element resistance R. Note that in this type of variation, the resonant frequencies of the resonators may not change substantially, since L may not be changing. Therefore, all the methods and examples presented for dynamic impedance matching may be used for the source circuit of the wireless power transmission system.

Note that, since the resistance R represents both the source coil and the reflected impedances of the device coils to the source coil, in FIGS. 9-12, as R increases due to the increasing U, the associated wireless power transmission efficiency increases. In some embodiments, an approximately constant power may be required at the load driven by the device circuitry. To achieve a constant level of power transmitted to the device, the required output power of the source circuit may need to decrease as U increases. If dynamic impedance matching is achieved via tuning some of the amplifier parameters, the output power of the amplifier may vary accordingly. In some embodiments, the automatic variation of the output power is preferred to be monotonically decreasing with R, so that it matches the constant device power requirement. In embodiments where the output power level is accomplished by adjusting the DC driving voltage of the power generator, using an impedance matching set of tunable parameters which leads to monotonically decreasing output power vs. R will imply that constant power can be kept at the power load in the device with only a moderate adjustment of the DC driving voltage. In embodiments, where the “knob” to adjust the output power level is the duty cycle dc or the phase of a switching amplifier or a component inside an Impedance Matching Network, using an impedance matching set of tunable parameters which leads to monotonically decreasing output power vs. R will imply that constant power can be kept at the power load in the device with only a moderate adjustment of this power “knob”.

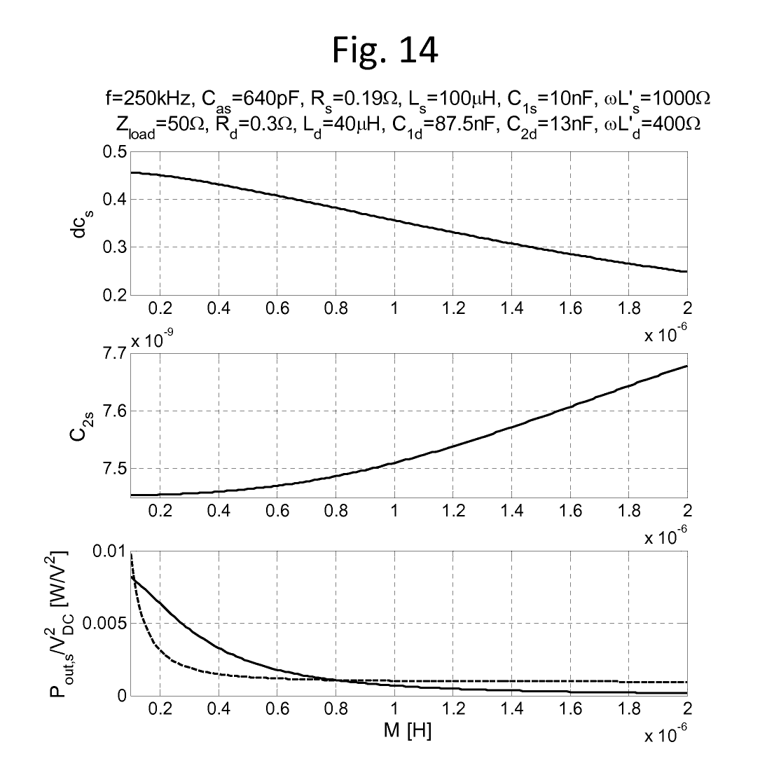

In the examples of FIGS. 9-12, if Rₛ=0.19Ω, then the range R=0.2-2Ω corresponds approximately to U_{sd}=0.3-10.5. For these values, in FIG. 14, we show with dashed lines the output power (normalized to DC voltage squared) required to keep a constant power level at the load, when both source and device are dynamically impedance matched. The similar trend between the solid and dashed lines explains why a set of tunable parameters with such a variation of output power may be preferable.

In some embodiments, dynamic impedance matching may be achieved at the source circuit, but impedance matching may not be achieved or may only partially be achieved at the device circuit. As the mutual inductance between the source and device coils varies, the varying reflected impedance of the device to the source may result in a variation of both the effective resistance R and the effective inductance L of the source inductive element. The methods presented so far or dynamic impedance matching are applicable and can be used for the tunable source circuit of the wireless power transmission system.

As an example, consider the circuit of FIG. 14, where f=250 kHz, Cₐ=640 pF, Rₛ=0.19Ω, Lₛ=100 μH, C₁ₛ=10 nF, ωL′ₛ=1000Ω, R_{d}=0.3Ω, L_{d}=40 μH, C_{1d}=87.5 nF, C_{2d}=13 nF, ωL′_{d}=400Ω and Zₗ=50Ω, where s and d denote the source and device resonators respectively and the system is matched at U_{sd}=3. Tuning the duty cycle dc of the switching amplifier and the capacitor C₂ₛ may be used to dynamically impedance match the source, as the non-tunable device is moving relatively to the source charging the mutual inductance M between the source and the device. In FIG. 14, we show the required values of the tunable parameters along with the output power per DC voltage of the amplifier. The dashed line again indicates the output power of the amplifier that would be needed so that the power at the load is a constant value.

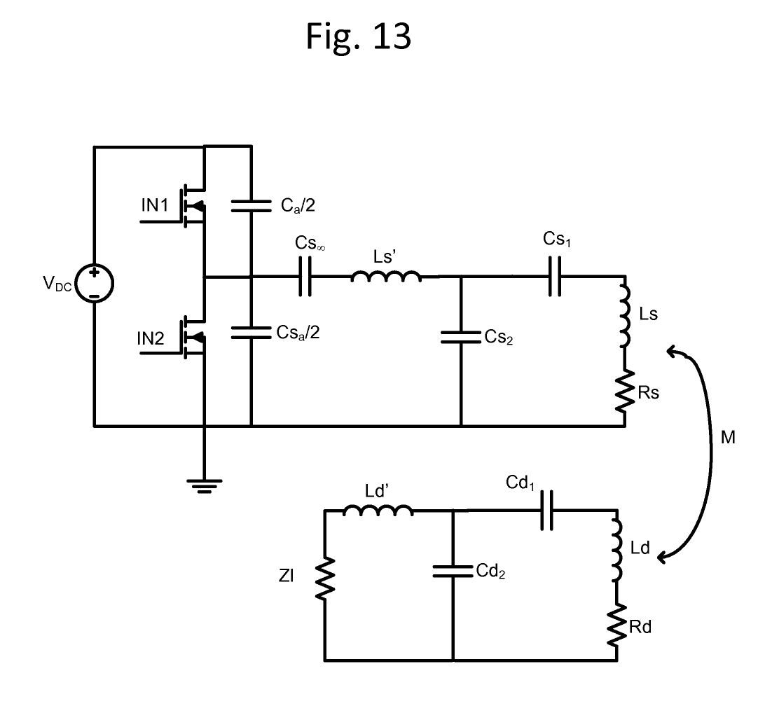

In some embodiments, tuning the driving frequency f of the source driving circuit may still be used to achieve dynamic impedance matching at the source for a system of wireless power transmission between the source and one or more devices. As explained earlier, this method enables full dynamic impedance matching of the source, even when there are variations in the source inductance Lₛ and thus the source resonant frequency. For efficient power transmission from the source to the devices, the device resonant frequencies must be tuned to follow the variations of the matched driving and source-resonant frequencies. Tuning a device capacitance (for example, in the embodiment of FIG. 13 C_{1d} or C_{2d}) may be necessary, when there are variations in the resonant frequency of either the source or the device resonators. In fact, in a wireless power transfer system with multiple sources and devices, tuning the driving frequency alleviates the need to tune only one source-object resonant frequency, however, all the rest of the objects may need a mechanism (such as a tunable capacitance) to time their resonant frequencies to match the driving frequency.

Fixed Tuned Wireless Power Transfer System Module Assembly

Wireless power transfer systems may be described as comprising modules and/or wireless power modules, and these modules may comprise high-Q magnetic resonators. Source modules may comprise source magnetic resonators, device modules may comprise device magnetic resonators and repeater modules may comprise repeater resonators. Wireless power modules may comprise additional electronic components that may be used for impedance matching, performance monitoring, tuning, communicating, and the like. Combinations of magnetic resonators and additional electronic components may be referred to as module sub-assemblies.

Magnetic resonators and/or the inductive loops of magnetic resonators of wireless power modules may be perturbed by extraneous objects and/or by materials, objects, circuits, and the like, of wireless power modules themselves. Module characteristics may be changed owing to changing positions of other modules, resonators, loads and the like of a wireless power transfer system. In embodiments, changes to magnetic resonator parameters and wireless power module performance may be compensated, mitigated, minimized, and the like, by using tunable components and networks of components as described above. In embodiments, tunable systems may comprise monitoring circuits, feedback circuits and the like. In embodiments, modules, sub-assemblies, and/or resonators may include tunable components.

In embodiments, it may be preferable to build, fabricate, manufacture, assemble, deploy, and the like, wireless power system modules that may not comprise tunable components and may not be tunable. Such wireless power transfer system modules may be referred to as “fixed tuned” modules, and systems utilizing these modules may be referred to as “fixed tuned” systems. In embodiments, such systems may comprise modules comprised of well characterized components with well known component values. The parameters of these assembled modules may be well known, and may be predictable to be within a range of acceptable values. Then, multiple copies of wireless power modules may be manufactured by simply selecting and placing the appropriate components on circuit boards and/or in enclosures. To insure quality of the modules, and to identify out-of-specification modules, it may be preferable to include an exemplary module assembly step that includes a measurement of a module parameter. Module parameters that may be measured include, but are not limited to, impedance, frequency, Q, and the like.

In embodiments, fixed tuned wireless power modules may be designed and assembled to efficiently deliver power wirelessly over power wirelessly over a range of module separations, orientations and arrangements, in a variety of operating environments, conditions and the like. In embodiments, the components of wireless power modules may be selected to optimize a performance parameter, such as end-to-end efficiency for example, at a nominal operating point or over a range of operating points. For example, a wireless power transfer system comprising a source pad and a smart phone device that is intended to be placed on the pad for charging may include modules that are optimized for those enclosures and that resonator arrangement. A wireless power transfer system that will charge a smart phone device while it is away from the pad, such as in a purse or back-pack, or next to the pad, may be optimized for that resonator arrangement. It should be noted that wireless power modules may be optimized for a certain arrangement, and may perform well over a much wider range of arrangements.

In embodiments, fixed tuned wireless power transfer systems may comprise modules comprised of components whose actual circuit values are no well known but are specified to be in a range, to halve a tolerance, to be above a minimum value and below a maximum value, and the like. The parameters of assembled modules using these components may not be well known, and may not be accurately predictable to be within a range of acceptable values. In embodiments to insure quality assembly of these modules, it may be preferable to include at least one exemplary module assembly step that includes a measurement of a module, sub-assembly, and/or resonator parameter. Measured parameters may include, but are not limited to, impedance, frequency, Q, and the like. If a module, sub-assembly, and/or resonator is determined to be out of specification, components of the resonators and/or sub-assemblies may be changed (e.g. added, removed, replaced, adjusted, and the like) until the module, sub-assembly and/or resonator are brought within the specification.

In embodiments where multiple copies of wireless power modules may be assembled for sale, multiple deployments, system redundancy, and the like, it may be preferable for wireless power modules to be assembled individually, and/or away from other modules in the whole system. For example, a manufacturing line may fabricate only wireless source modules, or only repeater modules, or the line may be switched between assembling source modules, device modules and repeater modules. Then, measurement steps in the module assembly process may benefit from temporarily adding at least one circuit component to the module, sub-assembly and/or resonator that mimics the impact of the other wireless power modules of the whole system on the module being assembled. Then the module, sub-assembly and or resonator may be characterized, adjusted, accepted, and the like, away from the other modules of the wireless power system. When the module, sub-assembly and or resonator performance is determined to be acceptable, the at least one temporary circuit component may be removed and the rest of the assembly process completed.

Components that are described as being temporary may be included in a resonator, a sub-assembly, a circuit, a module, and the like, for a measurement, characterization, verification, and the like, and then removed. Components that are described herein as temporary may not be part of the final assembled module, sub-assembly, resonator, circuit, and the like.

The inventors have identified a number of inventive steps that may be used to assemble, manufacture, and the like, wireless power modules for use in fixed tuned wireless power transfer systems.

In embodiments, the components comprised by modules, sub-assemblies resonators and the like, that determine the operating parameters of the wireless energy transfer system may have uncertainties in their actual parameter values or value variances, and the uncertainty, variance, tolerance and the like may be large enough to have an impact on the overall system performance. For example, purchased capacitors may be specified as having a nominal value of 100 pf, with a tolerance of ±10%, meaning the actual capacitance of each part is in the range of 90 pf to 110 pf. In embodiments, the resonant frequency of a resonator comprising a 90 pf capacitance may differ enough from the resonant frequency of a resonator comprising a 110 pf capacitance that wireless power transfer system performance is measurably impacted.

In embodiments, modules, sub-assemblies, resonators, and the like may need to be characterized as they are being assembled to determine whether the performance of the assembly will be satisfactory, given the uncertainty and/or range of actual values of the components used in the assembly. In embodiments, the actual component values or combined component values may be measured during assembly and/or manufacture of the energy transfer system modules and components may be added, removed, adjusted, and the like, and/or other components may be selected and included to mitigate, compensate, minimize, and the like, module performance variations and provide a substantially or satisfactorily equivalent overall performance of the modules despite variations of values of some or all of the components comprised by the modules.

In embodiments, the process of assembling and manufacturing source modules, repeater modules, device modules, and the like, of wireless power transfer systems may comprise a series of steps that may include measuring the values of specific components, and/or specific sub-assemblies, and/or specific resonators, and calculating or using look-up tables to determine the acceptability of those component and/or sub-assembly and/or resonator values as well as determining values for other or additional components that may be built into the modules. The process of assembling and manufacturing source modules, repeater modules, device modules and the like, of wireless power transfer systems may further comprise attaching components temporarily and measuring the parameters of networks of components, and adjusting, removing, and/or adding additional components to reach or approach the calculated and/or looked-up values of components, sub-assemblies, resonators, modules, and the like. Components that are described as being temporary may be included in a resonator, a sub-assembly, a circuit, a module, and the like, for a measurement, characterization, verification, and the like, and then removed. Components that are described herein as temporary may not be part of the final assembled module, sub-assembly, resonator, circuit, and the like.

The process of assembling and manufacturing source modules, repeater modules and device modules and the like, of wireless power transfer systems, may comprise test and/or verification steps that may be used to insure that modules assembled from multiple components with variable component values operate within the specified range eof acceptable module values. Module values may include, but are not limited to, component values, resonator values, impedance values, frequency values, loss values, quality factor values, power values, temperature values, field values, efficiency values, and the like.

In embodiments, the characterization of wireless power transfer system modules, sub-assemblies, resonators, and/or their associated components, and additional system components and electronic assemblies may be performed using a network analyzer, a vector network analyzer, an impedance analyzer, a time domain reflectometer (TDR), an LCR meter (L(inductance)C(capacitance)R(resistance)), a voltage wave standing wave (VSWR) meter, an impedance meter, and/or any equipment or combination of equipment capable of measuring impedance at a frequency and/or over a range of frequencies. It is to be understood that while the measurement techniques described herein may refer to a network analyzer, other measurement technologies, equipment, techniques, and the like may also be used or substituted as appropriate. Those skilled in the art will appreciate that although not explicitly described, some measurement techniques and equipment may require calibration steps or additional measurement steps that are omitted from the description herein.

In embodiments of wireless energy transfer systems, magnetic resonators and their associated components may be designed using any of the numerical, algebraic, computational, experimental, and the like, techniques described herein and in our previous patent applications, in embodiments, resonators and their associated components may be designed to achieve desired operational performance when they are loaded and/or perturbed. In embodiments, magnetic resonators and their associated components may be selected and placed based on certain system and environmental parameters such as the power loads or amplifiers used in the system, typical operating distances and orientations between resonators, and any surrounding lossy or metallic materials or objects. In embodiments of wireless energy transfer systems, the magnetic resonators and their associated components may be assembled and/or tuned using substantially fixed value components such as inductors, capacitors, and the like and may have limited or no adjustment capability after being assembled. In such so-called “fixed tuned” systems, the components that define the operating parameters of the wireless energy system may be selected for specific use conditions, environmental or surrounding conditions, power levels, and the like, and installed during module assembly and manufacture.

In embodiments the process of assembling and manufacturing source modules, repeater modules, device modules, and the like, of wireless power transfer systems may comprise a series of steps that include measuring the values of specific components, and or specific assemblies, and calculating or using look-up tables to determine the acceptability of those component and/or assembly values as well as the target values for other or additional components that will be built into the modules. The process of assembling and manufacturing source modules, repeater modules, device modules, and the like, of wireless power transfer systems may further comprise attaching components and measuring the parameters of networks of components, and adjusting or adding additional components to reach or approach the calculated and/or looked-up values of components and sub-assemblies.

In embodiments, magnetic resonator may comprise conducting loop inductors and a capacitance. In embodiments, the capacitance may comprise the self capacitance of the conducting loop and/or added capacitance. In embodiments, conducting loops of magnetic resonators may be connected to a capacitor, a network of capacitors, and/or a network of capacitors and inductors. Exemplary embodiments of algorithms that may be used for the assembly and/or manufacture of source modules, repeater modules, and device modules, comprising magnetic resonators, are described below. In embodiments, the time it takes to assemble or manufacture the wireless power modules may increase as the range of component value variability increases. In some embodiments, assembly and manufacture time may be limited by practical or commercial considerations. In such embodiments, an algorithm for assembly and manufacture may specify that measured, assembled, characterized, and the like, parameters be close to certain values, close enough to certain values, or within a certain range of values, that may yield acceptable system performance. In embodiments, some quantities may be estimated or approximated in certain steps of the assembly process.

In an exemplary assembly algorithm for “fixed-tuned” system modules and resonators, the conducting loops of the magnetic resonators may be characterized in their likely operating environment. The conducting loops may be preferably placed in positions that are as close to the target operating posit ions and environments as possible. The circuit boards, enclosures and the like, which may be placed next to or around the conducting loops during operation, may preferably be placed in the same positions with respect to the conducting loops during measurements and characterization. Alternatively, components, circuit boards, enclosures and the like or components that mimic the effects of the components, circuit boards and/or enclosures that are normally expected to be part of the environment of the wireless energy transfer system may be placed near the conducting loops during measurements. The conducting loops of different resonators in the system may be preferably separated by the operating distance and/or positioned in the target operating orientation. In embodiments, if the resonators of the wireless power transfer system are perturbed by their environment, the resonator properties may be measured in that perturbing environment.

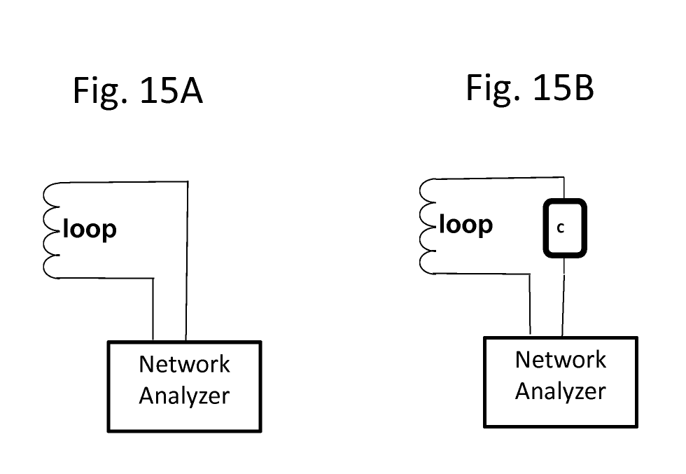

In the exemplary embodiment described here, the inductance, L, and resistance, R, of a conducting loop to be used in a resonator of a wireless power transfer system, may be measured using a network analyzer as shown in FIG. 15A, while the conducting loops of other resonators in the system are open-circuited. The inductance and resistance of other conducting loops to be used in resonators of the wireless power system, may be measured using a network analyzer as shown in FIG. 15A. In a similar manner (i.e. while the conducting loops of the other resonators in the system are open-circuited).

In embodiments, a capacitance C may be connected to a conducting loop as depicted in FIG. 15B. The conducting loop forms an inductor and may comprise an air core, a magnetic material core, a magnetic material structure or a combination of air and magnetic materials. In embodiments, magnetic material cores and/or structures may be hollow and may enclose other materials, objects, and/or circuits. The capacitance value of C may be chosen to cancel the imaginary part of the measured impedances of the conducing loop at the targeted resonant and/or operating frequency. Estimates for the capacitance value of C that achieves the desired operating frequency, f, may be calculated based on the measured inductance of the conducting loop, L, and the desired operating frequency, f according to:

$$C = \frac{1}{{ω}^{2} L} = \frac{1}{{( 2 π f )}^{2} L}$$

where the angular operating frequency, ω=2πf.

In embodiments, if the capacitance of C is well known, the operating frequency of this LC resonator should also be well known, and further characterization of the resonator may not be necessary. In embodiments, the resonant frequency of a resonator can be experimentally verified by measuring the imaginary impedance of the loop/C combination and determining that the imaginary impedance is approximately zero at the target operating frequency. In embodiments, the inductance of the conducting loop and/or the capacitance of C, may be changed in order to make the imaginary impedance of the inductor/capacitor combination close to zero. Note that the inductor/capacitor imaginary impedance may not be perfectly cancelled (i.e. 0Ω). In embodiments, imaginary impedances of approximately 1Ω, or approximately 2Ω, or approximately 5Ω, may be sufficient. In fixed tuned embodiments, the values of L and C may not be tuned while the wireless power module is operating.

In embodiments, C may comprise one capacitor or multiple capacitors configured to have an equivalent capacitance of C. In embodiments, C may comprise at least one capacitor and at least one inductor configured to have an equivalent capacitance of C. C may be a variable capacitance. C may be a continuously variable capacitance or it may be a discretely variable capacitance, such as may be realized using a switchable capacitor bank or switchable component bank comprising capacitors and inductors. In embodiments, C may comprise any circuit elements including switches, inductors, splitters, and the like that may be used to realize an effective capacitance of C. In embodiments, C may have a high Q. In embodiments, C may have a low ESR (effective series resistance). In embodiments C may have a Q>500. In embodiments, C may have a Q>1000. In embodiments, the conducting loop inductor may be any variety of inductor including, but not limited to, inductor arrangements discussed in this and previous specifications.

In embodiments, a magnetic resonator comprising an inductance and capacitance as described above may be characterized using a separate measurement coil connected to the network analyzer or any appropriate impedance analyzing equipment, and the parameters of the magnetic resonator may be measured with the network analyzer using signals induced in the separate measurement coil. The separate measurement coil may be any conductor forming a loop or loops and may be small enough that, when it is brought close to one of the resonators being assembled into the wireless power system, it does not efficiently couple to other conducting loops and/or resonators of the wireless power system.

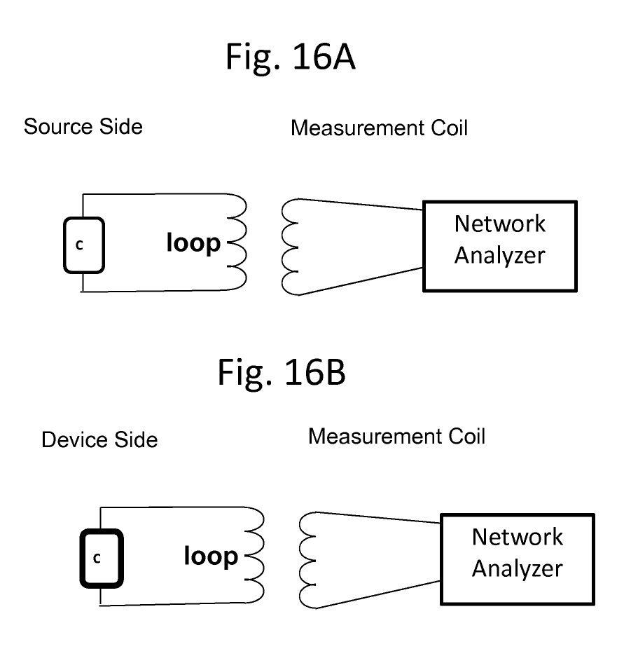

The measurement coil may be connected to the network analyzer and may be brought close enough to inductively couple to a conducting loop-capacitor combination as depicted schematically in FIG. 16A. In embodiments, the conducting loop and parallel capacitance, C, may be assembled in a closed circuit as shown in FIG. 16A. The real part of the measured impedance for this arrangement may be plotted on the network analyzer and may exhibit a peak in the vicinity of the operating frequency, f. In an exemplary step of the assembly algorithm, the value of C may be adjusted until the frequency at which the real part of the measured impedance peaks is at the target operating frequency, f, or is determined to be close enough to the target operating frequency, f. How accurately C needs to be adjusted will be application dependent.

The frequency width of this peaked impedance measurement plot, measured where the amplitude of the impedance is half the value of the peak impedance, may be referred to as the Full Width at Half Maximum of the peak (FWHM). Some network analyzers and other impedance measurement equipment may automatically measure, compute, and report this quantity directly. In some embodiments, the impedance data as a function of frequency may be downloaded from the network analyzer and mathematical fitting routines may be used to determine the exact shape of the impedance function and may yield extremely accurate measures of the impedance function's frequency FWHM. In embodiments, the frequency width of the impedance function may be estimated to speed up assembly time or to reduce the complexity of the assembly process. The measured values of the width of the impedance function may be used to calculate loss rates for certain components in the wireless energy transfer system.

In embodiments, the loss rate of high-Q magnetic resonators may be determined using a network analyzer and a separate measurement coil. In embodiments, the FWHM of the impedance function measured by a separate measurement coil inductively coupled to a resonator may yield at accurate the measure of the resonator loss or resistance, R.

R=2πL*FWHM

Γ=π·FWHM

Note that Γ is the resonance width of the resonator. If the resonator has been characterized in its operating environment, including surrounding lossy and metallic objects, this measured resonance width is the perturbed resonance width of the resonator. The perturbed Q of the resonator. Q₍ₚ₎, may then be determined from the equation

$${Q}_{( p )} = \frac{ω L}{R} .$$

The measurement procedure described in the previous paragraphs may be performed for any number of magnetic resonators designed for use in a wireless energy transfer system. In an exemplary embodiment, the measurement procedure on each conducting loop may be performed while all other conducting loops are open-circuited and such that the peak in the real part of the measured impedance occurs at similar frequencies. As with other steps, the frequencies should be close enough to support efficient system operation. Variability in component values, assembly techniques, and system specifications may influence the range of acceptable peak frequency values. How accurately components need to be adjusted will be application dependent.

In fixed tuned system embodiments, it may be desirable to characterize the modules and/or sub-assemblies, and or resonators of the source, device and repeater modules in a like operating scenario in order to choose the fixed tuned components that may yield the best overall system performance. The definition of best performance may be application dependent, but may include considerations of operating range distance, efficiency, power level, field level, module cost, module size, module complexity, and the like.

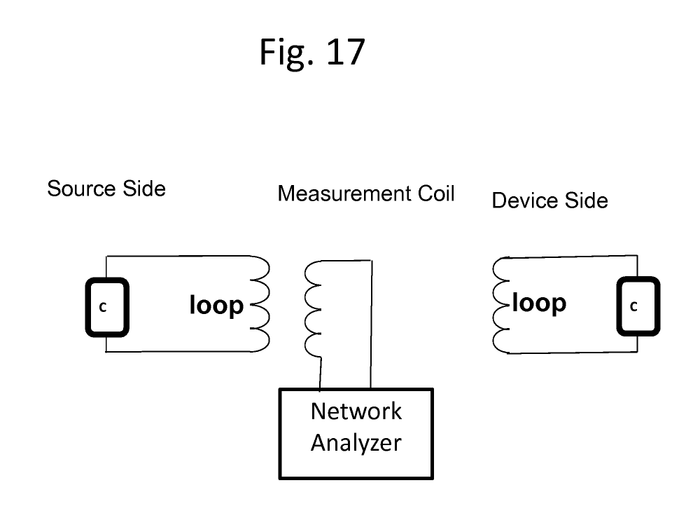

In an exemplary step of an exemplary assembly algorithm for fixed tuned wireless power transfer systems, the coupling between two magnetic resonators may be determined experimentally. In an exemplary method for determining the coupling between two resonators, a separate measurement coil may be attached to the network analyzer and brought close to a first resonator that is wirelessly coupled to a second resonator as shown in FIG. 17. The measurement coil should be placed in such a position as to couple effectively to the first resonator and not to the second resonator. In an exemplary embodiment, the first resonator may be a source resonator of a wireless power transfer system and the second resonator may be a device resonator of the wireless power transfer system and the resonator parameters may be identified mathematically by subscripts “s” and “d” respectively. Note that the procedures and calculations presented throughout this specification are general to magnetic resonators and that designations of source, device and repeater are not meant to be restrictive, but rather illustrative. Substitutions of other subscripts and/or descriptions of other resonators, additional resonators, and the like, should not be considered as departing from the teachings herein.

The real part of the measured impedance of the first resonator may be measured and plotted on the network analyzer. The measured impedance may exhibit two peaks, and the frequencies of those peaks may be on either side of the operating frequency, f. The difference between the peak frequencies may be referred to, as a Frequency Splitting parameter FS. This frequency splitting parameter may be used to estimate the coupling factor, k, and/or the coupling rate, κ, between the resonators in heir nominal operating arrangement. By defining the parameter D, D=2π·FS, the coupling factor k, along with other measured and or calculated quantities Γₛ and Γ_{d} may be used to calculate an estimated Figure-of-Merit, U, of the system according to the following formulae:

$$u = \frac{{( {Γ}_{s} + {Γ}_{d} )}^{2} + {D}^{2} / 2 + ( {Γ}_{s} + {Γ}_{d} ) \sqrt{{( {Γ}_{s} + {Γ}_{d} )}^{2} + \frac{{D}^{4}}{4 {Γ}_{d}^{2}} + {D}^{2}}}{2 ( {Γ}_{s}^{2} + 2 {Γ}_{s} {Γ}_{d} )}$$

$$U = \sqrt{u - 1.}$$

In some embodiments, the frequency-dependent impedance data may be downloaded from the network analyzer and mathematical fitting routines may be used to determine the shape of the impedance function, the appropriate measure of that function's frequency splitting and the associated estimates of k and U. In some embodiments, if the coupling factor k is relatively large, it may not be accurately determined using the equation above and other measurement techniques may be preferably used to determine k.

Then the estimated wireless efficiency, η, of the energy transfer between source and device conducting loop/C combinations is

$$η = {( \frac{U}{1 + \sqrt{1 + {U}^{2}}} )}^{2}$$

In embodiments of fixed tuned wireless power transfer systems, module assemblies comprising the magnetic resonators may require additional components be added to the module to achieve impedance matching between power sources and power loads of the wireless power system for example. In embodiments, target impedances may be chosen for source and device resonators to optimize system performance at certain resonator arrangements and for certain power loads. In embodiments, the target impedances may be chosen to obtain specified system performance over specified system ranges, such as ranges of resonator separations, offsets, orientations, and the like and/or ranges of power loads. In embodiments, the target impedances may be chosen to optimize the required energy stored in the magnetic resonators or they may be chosen to optimize the end-to-end power deliver of the system or they may be chosen based on some other desired system feature or characteristic. In embodiments, the target impedances may be chosen to optimize system performance for system modules comprising full-bridge power components (e.g. amplifiers, rectifiers) and/or modules comprising half-bridge components. The inventors have discovered that despite how the target impedances are determined, accurate source and device modules for efficient wireless power transfer systems can be achieved using the following exemplary steps.

An exemplary step in a module assembly and/or characterization process may include determining target impedances seen by the power source and power load of a wireless power transfer system.

In an exemplary embodiment, the target impedances for source and device resonators, Z₀ₛ and Z_{0d}, may be calculated using the following equations:

P_{g}=Pₗ/η/(η_{electronics})

Z₀ₛ=V_{amp,DC}²/P_{g}8/π²

Z_{0d}=V_{rec,DC}²/Pₗ8/π²

where P_{g} is the necessary power to be supplied from the power generator, Pₗ is the desired power to be delivered to the load, η_{electronics} is the estimated efficiency of the electronics in the system (e.g. amplifier, rectifier, etc.), V_{amp,DC} is the DC bus voltage of the amplifier, and V_{rec,DC} is the target DC voltage at the output of the rectifier, which may typically be designed to be less than the maximum voltage rating for the device electronics following the rectifier and V_{rec,DC} is the target DC voltage at the output of the rectifier, which may typically be designed to be less than the maximum voltage rating for the device electronics following the rectifier.

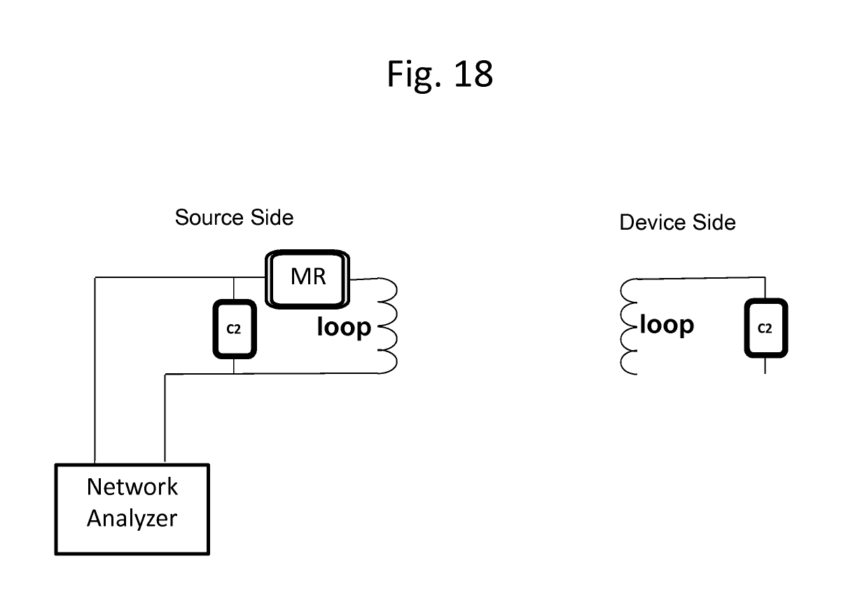

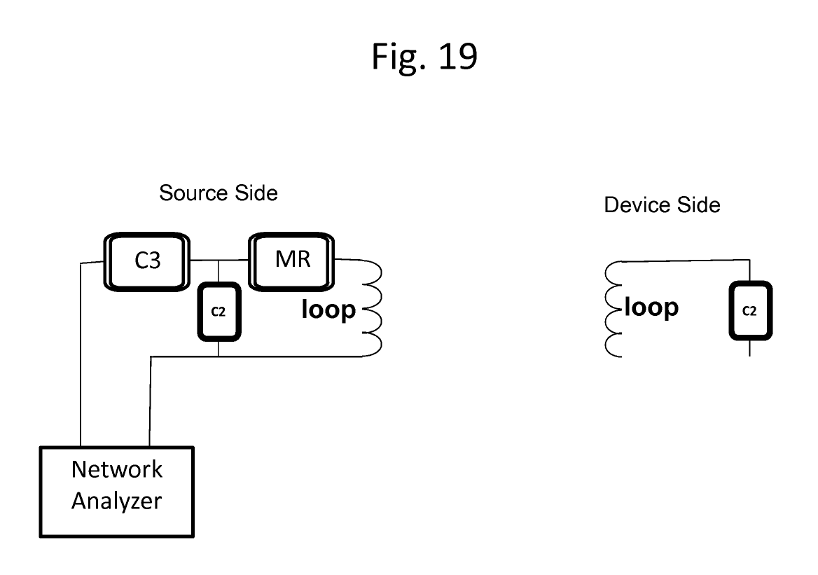

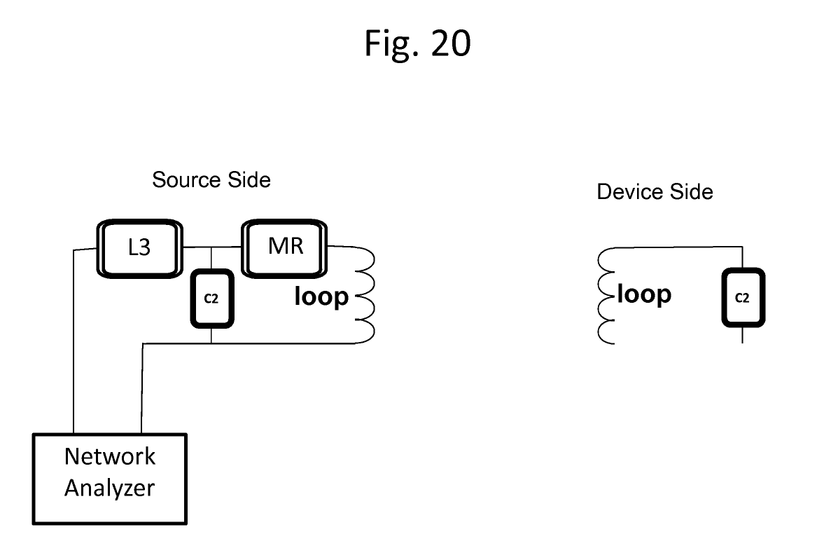

In embodiments, an assembly method may include temporarily connecting a matching resistor (MR) in series with a conducting loop as shown in FIG. 18. During the matching procedure of one conducting loop, all other conducting loops may preferably be open circuited, therefore this matching resistor may be simulating the reflected impedance of the other modules in the final system. In an embodiment of one source and one device, when full impedance matching is obtained (both at the source and the device), the effective resistance of the source conducting loop (namely the actual resistance of the source loop R_{S} plus the reflected impedance from the device R_{SM}) is Rs\sqrt{1+U²} and, similarly, the effective resistance of the device loop is R_{d}\sqrt{1+U²}, where R_{d} is the actual resistance of the device loop. Therefore, in an embodiment, a source matching resistance Rₛₘ and a device matching resistance, R_{dm}, may be calculated using:

Rₛₘ=R_{S}(\sqrt{1+U²}−1)

R_{dm}=R_{d}(\sqrt{1+U²}−1)

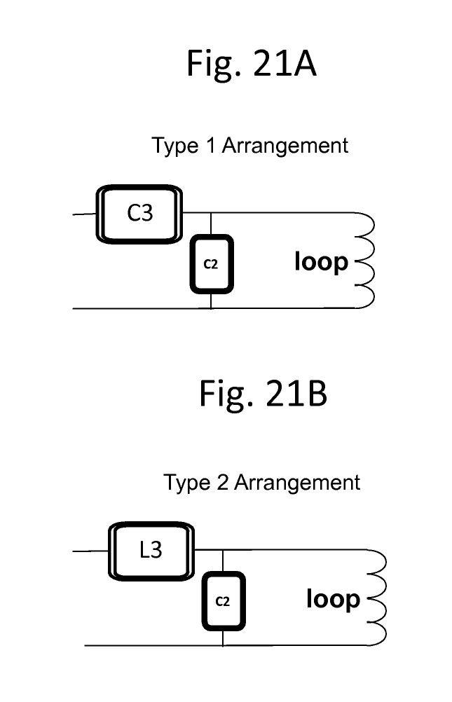

In an exemplary embodiment, a wireless energy transfer system may comprise a source magnetic resonator and a device magnetic resonator. The magnetic resonators may be configured as shown in FIGS. 21A and 21B, and may be referred to in this example as a Type 1 arrangement and a Type 2 arrangement. Although we will discuss this exemplary embodiment, this application, along with other previous applications, describe systems comprising more than two resonators and with circuit designs other than those referred to here as Type 1 and Type 2. It is to be understood that the methods and techniques described here could be extended to the other systems and resonators described previously.

The above measured and calculated values of conducting loop inductance and effective resistance, and the calculated values of the target impedance for the source and device resonators may be used to specify the C2/C3 or C2/L3 values for the source and device magnetic resonators.

In embodiments, the following equations may be used to determine the resonator C2 and C3 values of the source resonator for a Type 1 arrangement:

$$ω \text{?} = \frac{2 π f * \text{?} - \sqrt{( 2 π f * \text{?} ) \text{?} ( \text{?} / \text{?} ) - \text{?} ( 1 - \text{?} / \text{?} )}}{( 2 π f * \text{?} ) \text{?} + \text{?}}$$

$$ω \text{?} = \frac{( \text{?} / \text{?} ) ω \text{?}}{1 - ( 2 π f * \text{?} ) ω \text{?} - ( \text{?} / \text{?} )}$$

$$\text{?} \text{indicates text missing or illegible when filed}$$

In embodiments, the following equations may be used to determine the resonator C2 and L3 values of the source resonator for a Type 2 arrangement:

$$ω \text{?} = \frac{2 π f * \text{?} + \sqrt{( 2 π f * \text{?} ) \text{?} ( \text{?} / \text{?} ) - \text{?} ( 1 - \text{?} / \text{?} )}}{( 2 π f * \text{?} ) \text{?} + \text{?}}$$

$$ω \text{?} = \frac{1 - ( 2 π f * \text{?} ) ω \text{?} - ( \text{?} / \text{?} )}{( \text{?} / \text{?} ) ω \text{?}}$$

$$\text{?} \text{indicates text missing or illegible when filed}$$

In an exemplary embodiment, the preceding equations and measurements may be used to calculate the capacitance and/or inductance values that may be used to realize the magnetic resonators of a wireless power transmission system. In an exemplary embodiment, parameters may be measured as the resonators are being assembled that ensure the deployed component values are close enough to the as-designed values to ensure adequate system performance.

In embodiments, the conducting loop and its associated electronics may be characterized as it is assembled. Before assembly, components or component networks with component values similar to those calculated as described above may be collected for integration into the wireless energy transfer modules. In embodiments printed circuit boards, device electronics boards, amplifier boards, or source electronic boards may include a resistor component for the purpose of performing the tuning and matching operation. The resistor component may be populated and configured to connect to the coil during the tuning phase of assembly and may be removed or configured to disconnect via fuses, jumpers, switches and the like after tuning has been completed. In embodiments the matching resistor may be a variable resistor that may be dynamically changed by mechanical or electronic means. A variable resistor may be used to tune the resonators for various loading conditions or various U's without changing the physical resistor. The matching resistor may be adjusted to minimal or no resistance value following the tuning operation.

In another step of an exemplary assembly algorithm, the method may further require inserting a capacitor C2 close to the calculated value C2, and connecting that circuit to a network analyzer set to the operating frequency of the system, as shown in FIG. 18. Using the network analyzer, the real part of the impedance may be measured and compared to the calculated impedance Z₀ₛ. The value of C2 may be adjusted to get as close to the calculated value as practically possible.

If using a Type 1 arrangement, the imaginary part of the measured impedance value should be positive. If it is negative, then C2 may be reduced until the real part of the impedance is as close to the calculated impedance as practically possible and the imaginary part of the measured impedance is positive. If using a Type 2 arrangement, the imaginary part of the measured impedance value should be negative. If it is positive, then C2 may be increased until the real part of the impedance is as close to the calculated impedance as practically possible and the imaginary part of the measured impedance is negative.

For a Type 1 arrangement, the calculated value of capacitance C3 is added in series with the loop as shown in FIG. 21A. For a Type 2 arrangement the calculated value of inductance L3 is added in series with the loop as shown in FIG. 21B and the circuit is attached to the network analyzer. The values of C3 or L3 may then be adjusted to get the imaginary part of the measured impedance as close as practically possible to zero Ohms (or any other value that may be desired, for example, for a class D or class E amplifier or rectifier).

When the measured impedance is close to (˜within 5% of) the calculated target impedance Zo, the matching resistor from the source loop may be disconnected.

With the source loop open-circuited the procedure for adjusting and adding C2, C3 or L3 is performed for the device side. The same formulas as above (with index d instead of s) can be used to estimate the components required also for the device resonator for a Type 1 (C2/C3) or Type 2 (C2/L3) arrangement.

When both sides have been assembled according to the described procedure, the source and device circuits are ready to be attached to an amplifier or a load respectively.

Although the assembly method was described for a system of two resonators, the same procedure may be followed for a system using any member of resonators using the procedures outlined above. In the system each resonator may be independently tuned and its components adjusted. In some configurations some additional adjustment may be necessary. For example, for systems including a repeater resonator between a source and a device resonator, additional adjustment to C2 and/or C3 or L3 may improve the performance.

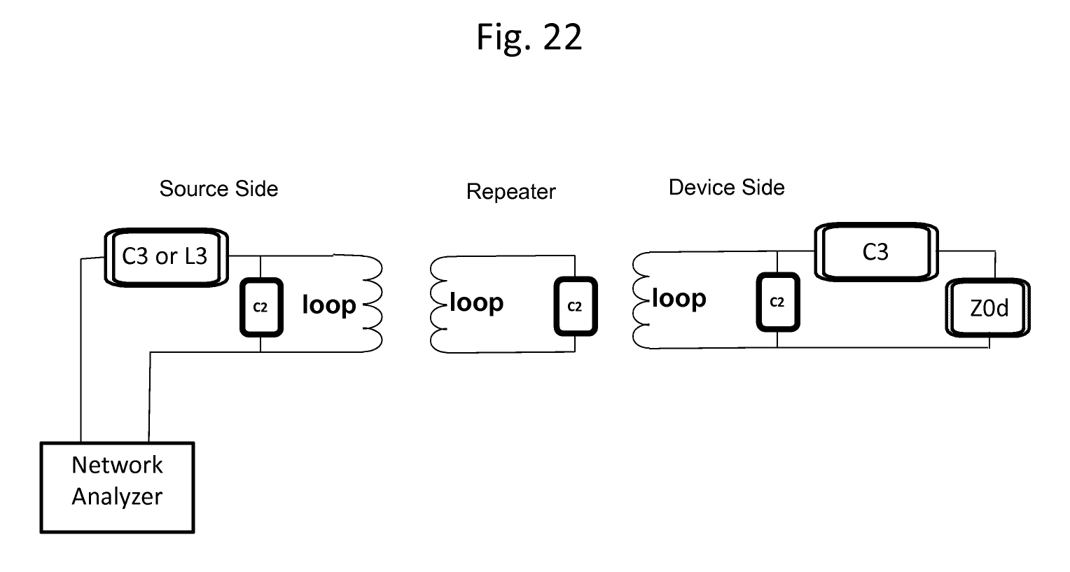

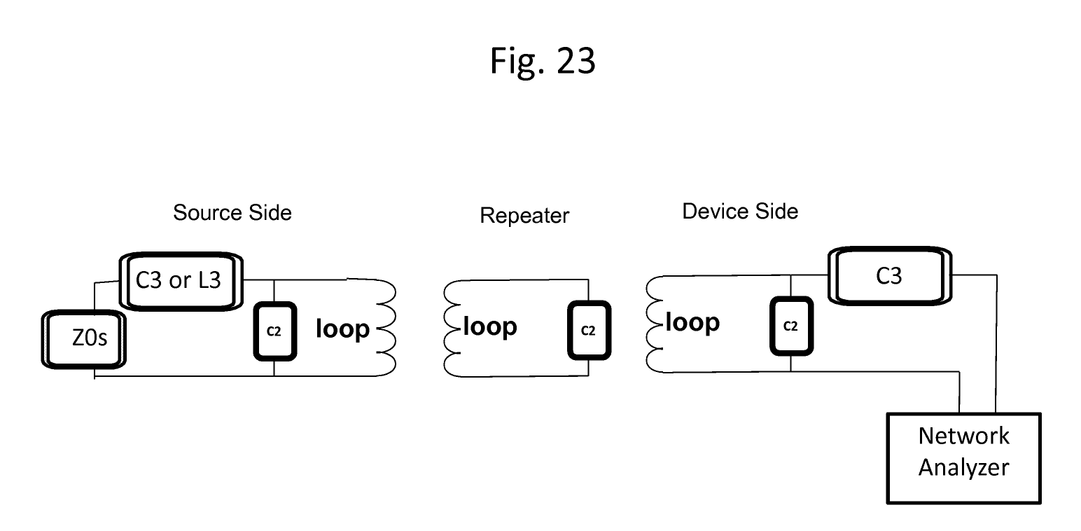

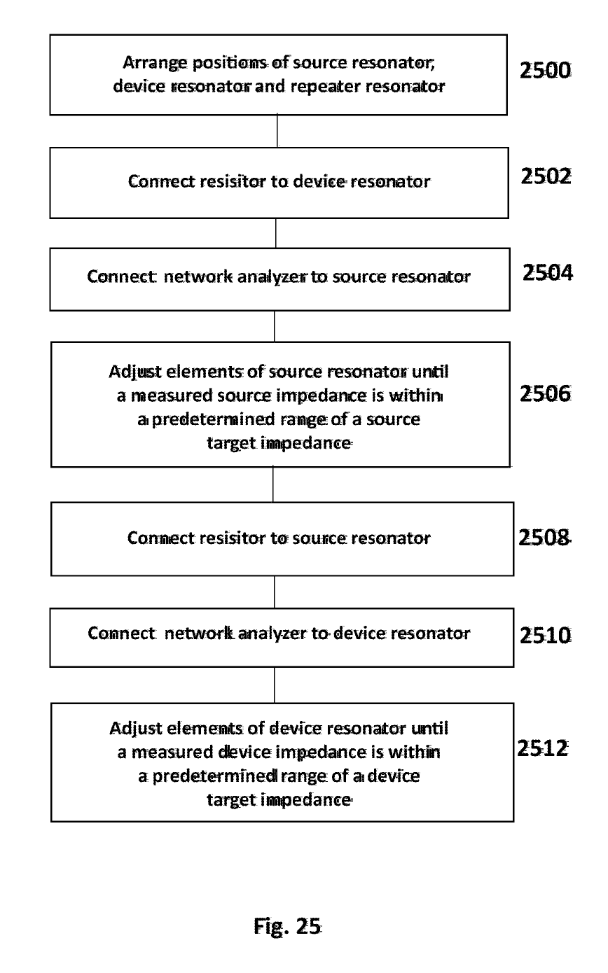

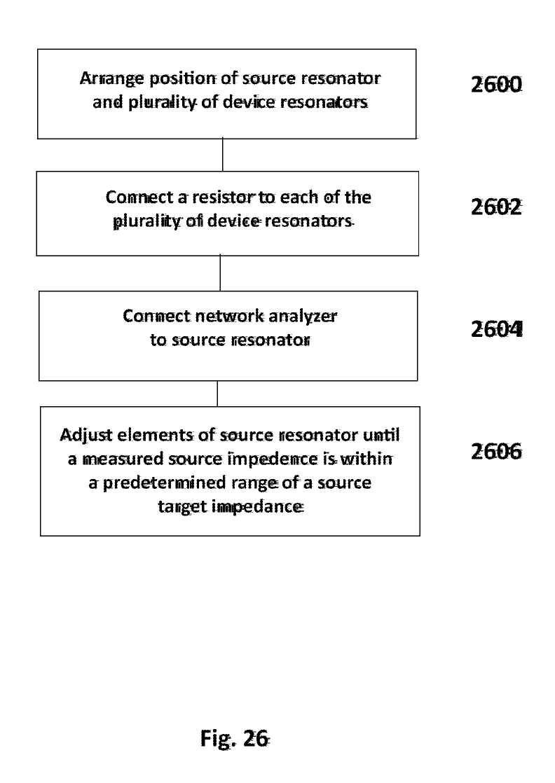

With reference to FIG. 25, there is illustrated an exemplary and non-limiting embodiment of a method for adjusting source and device resonator parameters to compensate for the effects of a repeater resonator. Specifically, in a system that includes a repeater resonator along with a source and a device, after the source and device have been tuned according to the above procedure, it may be desirable to perform adjustments to compensate for effects of the repeater resonator according to the calculated target impedance values for the source and device. The steps of FIG. 25 are described with reference to the system configurations of FIG. 22 and FIG. 23. First, at step 2500 the system is arranged in its approximate operating configuration as shown in FIG. 22. The repeater resonator may be placed in any location in the vicinity of the source resonator and the device resonator. Specifically, in accordance with an exemplary embodiment, the repeater resonator is placed in a position and/or vicinity sufficient to enable the transmission of power between and amongst the source resonator, the repeater resonator and the device resonator. Next, at step 2502, a resistor having a resistance approximately equal to the value of the calculated device target impedance (Z_{0d}) described above is connected to the device resonator as shown in FIG. 22. At step 2504, a network analyzer is connected to the source resonator as shown.

Next, at step 2506, power may be added to the system and component values of the source resonator (C2, C3 or L3) may then be adjusted until the source impedance measured by the network analyzer is approximately equal to the calculated source target impedance (Z₀ₛ). Note that the source resonator may comprise either one or more adjustable capacitive elements (C3) or one or more adjustable inductive elements (L3) depending on whether the source resonator is a Type 1 or Type 2 arrangement. In exemplary embodiments, component values of the source resonator may be adjusted until the measured source impedance is within a predetermined range extending around and including the calculated source target impedance (Z₀ₛ). Such adjustments may be performed manually or in an automated fashion.

Next, at step 2508, a resistor matching the calculated source target impedance is attached to the source resonator and, at step 2510 the network analyzer is connected to the device resonator as shown in FIG. 23. Then, at step 2512, power may be added to the system and the device resonator component values C2 and C3 may be adjusted until the calculated target device impedance is reached. In exemplary embodiments, component values of the device resonator may be adjusted until the measured device impedance is within a predetermined range extending around and including the calculated device target impedance (Z_{0d}). Such adjustments may be performed manually or in an automated fashion.

The process of measuring the impedance of the source and the device while the other source or device is connected to the appropriate resistor may be performed in iterative fashion. For example, after performing steps 2508-2512, steps 2502-2506 may be performed again. Upon completing a second iteration of steps 2502-2506, steps 2508-2512 may be performed again. In this manner, steps 2502-2506 and steps 2508-2512 may be repeatedly performed in an iterative fashion.

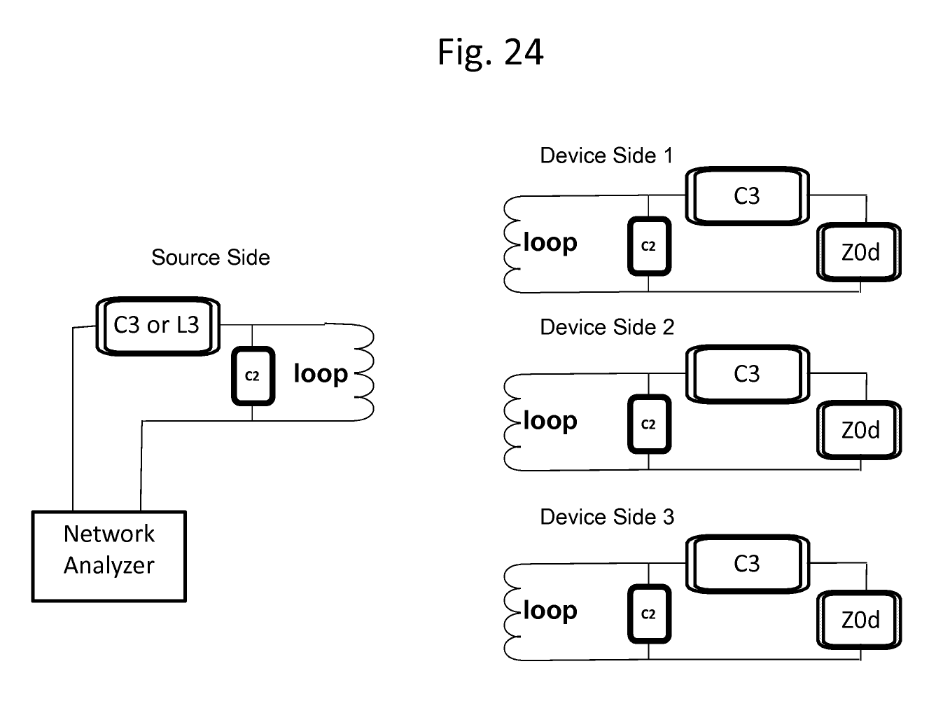

In a system that includes multiple devices, after a source resonator and each of multiple device resonators have been tuned according to the above procedure, additional adjustment may be made to compensate for effects of the multiple device resonators according to the calculated target impedance values for the source resonators and device resonators. With reference to FIG. 26, there is illustrated an exemplary and non-limiting embodiment of a method to perform such additional adjustment. First, at step 2600, the system, comprising the source resonator and a plurality of device resonators is arranged in a manner approximating the operating configuration of the system. Next, at step 2602, a resistor comprising a resistance value approximately equal to the calculated device target impedance (Z_{0d}) described above, is connected to each device resonator as depicted in FIG. 24. Next, at step 2604, a network analyzer is connected to the source resonator as shown in FIG. 24.

Next, at step 2606, power may be added to the system and component values of the source resonator (C2, C3 or L3) may be adjusted until the source impedance measured by the network analyzer is approximately equal to the calculated source target impedance (Z₀ₛ). Note that the source resonator may comprise either one or more adjustable capacitive elements (C3) or one or more adjustable inductive elements (L3) depending on whether the source resonator is a Type 1 or Type 2 arrangement. In exemplary embodiments, component values of the source resonator may be adjusted until the measured source impedance is within a predetermined range extending around and including the calculated source target impedance (Z₀ₓ). Such adjustments may be performed manually or in an automated fashion.

Those skilled in the art will understand that the equations used to calculate the circuit parameters of the components in the magnetic resonators may be altered to describe different amplifier architectures, rectification schemes, resonator circuit arrangements, and the like.

Note that while certain steps have been described for assembling resonators, other algorithms that use only some of these steps, or that change the order of the steps, are within the scope of this invention. Note that changes to the equations used to calculate the component values used to assemble the resonators may be changed without departing from the scope and intent of the methods, measurements and algorithms described herein. Note too that in some cases, equations and techniques may provide estimates of values and system parameters. In cases where we have described steps that are implemented to change a certain impedance or resistance, terms such as close to 0 ohms may mean values of 1 ohm, 2 ohms or 5 ohms, or anything in between. Similarly, values of k, Q, U, η, voltages, and the like, may be estimates or approximations without departing from the scope and intent of this disclosure.

While the invention has been described in connection with certain preferred embodiments, other embodiments will be understood by one of ordinary skill in the art and are intended to fall within the scope of this disclosure, which is to be interpreted in the broadest sense allowable by law.

All documents referenced herein are hereby incorporated by reference in their entirety as if fully set forth herein.

What is claimed is:

1. A method comprising:
a) providing a source resonator comprising a first conductive loop in parallel with a first capacitive element and in series with a first adjustable element the source resonator having a source target impedance;
b) providing a device resonator comprising a second conductive loop in parallel with a second capacitive element and in series with a second adjustable element the device resonator having a device target impedance;
c) providing a repeater resonator;
d) arranging a position of the repeater resonator substantially in the vicinity of a position of the source resonator and a position of the device resonator;
e) connecting a resistor corresponding to the device target impedance in series with the second conductive loop;
f) connecting a network analyzer in series with the first conductive loop;
g) adjusting at least one of the first capacitive element and the first adjustable element until a measured impedance of the source resonator is within a predetermined range of the source target impedance;
h) connecting a resistor corresponding to the source target impedance in series with the first conductive loop;
i) connecting the network analyzer in series with the second conductive loop; and
j) adjusting at least one of the second capacitive element and the second adjustable element until a measured impedance of the device resonator is within a predetermined range of the device target impedance.

2. The method of claim 1 wherein steps e-g are performed in an alternating iterative fashion with steps h-j.

3. The method of claim 1 wherein at least one of the adjustable elements comprises a capacitor.

4. The method of claim 1 wherein at least one of the adjustable elements comprises an inductor.

5. A method comprising:
providing a source resonator comprising a first conductive loop in parallel with a first capacitive element and in series with a first adjustable element the source resonator having a source target impedance;
providing a plurality of device resonators each comprising a conductive loop and having a device target impedance;
connecting, for each of the plurality of device resonators, a resistor corresponding to the device target impedance in series with the conductive loop of each of the plurality of device resonators;
connecting a network analyzer in series with the first conductive loop; and
adjusting at least one of the first capacitive element and the first adjustable element until a measured impedance of the source resonator is within a predetermined range of the source target impedance.

6. The method of claim 5 wherein the first adjustable element comprises a capacitor.

7. The method of claim 5 wherein the first adjustable element comprises an inductor.

8. A method comprising:
a) providing a source resonator comprising a first conductive loop in parallel with a first capacitive element and in series with a first adjustable element the source resonator having a source target impedance;
b) providing a device resonator comprising a second conductive loop in parallel with a second capacitive element and in series with a second adjustable element the device resonator having a device target impedance;
c) providing a repeater resonator;
d) arranging a position of the resonator substantially in the vicinity of a position of the source resonator and a position of the device resonator;
e) connecting a resistor corresponding to the device target impedance in series with the second conductive loop;
f) adjusting at least one of the first capacitive element and the first adjustable element until an impedance measured in series with the first conductive loop is within a predetermined range of the source target impedance;
g) connecting a resistor corresponding to the source target impedance in series with the first conductive loop; and
h) adjusting at least one at the second capacitive element and the second adjustable element until an impedance measured in series with the second conductive loop is within a predetermined range of the device target impedance.

9. The method of claim 8 wherein steps e-f are performed in an alternating iterative fashion with steps g-h.

10. The method of claim 8 wherein at least one of the adjustable elements comprises a capacitor.

11. The method of claim 8 wherein at least one of the adjustable elements comprises an inductor.
